(19) United States
(12) Patent Application Publication
(10) Pub. No.: US 2026/0293391 A1
(43) Pub. Date: Sep. 24, 2026

(54) MANUFACTURING METHOD OF DISPLAY DEVICE

(71) Applicant: Samsung Display Co., Ltd., Yongin-si (KR)

(72) Inventors: Tae Hee LEE, Yongin-si (KR); Jae Gwang UM, Yongin-si (KR); Moon Won CHANG, Yongin-si (KR)

(21) Appl. No.: 19/425,087

(22) Filed: Dec. 18, 2025

(30) Foreign Application Priority Data
Mar. 19, 2025 (KR) 10-2025-0035227

(51) Int. Cl. H10H 29/01; H10H 29/02

(52) U.S. Cl. CPC H10H 29/012; H10H 29/02; H10H 29/0362; H10H 29/0364

(57) ABSTRACT

A method for manufacturing a display device includes: forming a first electrode on a first substrate; forming a via layer on the first substrate, and forming a reflective partition wall on the via layer; forming a conductive bonding pattern on the first electrode; arranging a second substrate, on which a light emitting element is arranged, on the conductive bonding pattern, wherein the light emitting element includes a contact electrode arranged on one surface, and wherein an adhesive layer is on one surface of the second substrate; and bonding the light emitting element using the conductive bonding pattern by irradiating the adhesive layer with a laser beam by a laser irradiator and pressing the light emitting element with the conductive bonding pattern by pressing a pressing member in a direction in which the conductive bonding pattern is arranged on the second substrate.

### CROSS-REFERENCE TO RELATED APPLICATION

This application claims priority to and the benefit of Korean Patent Application No. 10-2025-0035227, filed on Mar. 19, 2025, in the Korean Intellectual Property Office, the entire disclosure of which is incorporated by reference herein.

### BACKGROUND

### 1. Field

The present disclosure relates to a method for manufacturing a display device.

### 2. Description of the Related Art

As the information society develops, the demand for display devices for displaying images is increasing in various forms. The display device may be a flat panel display device such as a liquid crystal display, a field emission display, a light emitting display, and/or the like.

The light emitting display device may include an organic light emitting display device including an organic light emitting diode (OLED) element as a light emitting element, and an ultra-small light emitting display device including a micro light emitting diode element (hereinafter referred to as a micro light emitting element) as a light emitting element. Because the micro light emitting diode element is made of an inorganic material, it has the advantage of having a long lifespan due to less deterioration issues compared to an organic light emitting diode (OLED) element.

The manufacturing process of a light-emitting display device requires a process for bonding ultra-small light-emitting diode elements to a panel.

### SUMMARY

Aspects and features of embodiments of the present disclosure are to provide a method for manufacturing a display device that optimizes the height of a reflective partition wall to reduce or prevent bonding failure of a light emitting element.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a method for manufacturing a display device comprising: forming a first electrode on a first substrate; forming a via layer on the first substrate, and forming a reflective partition wall on the via layer; forming a conductive bonding pattern on the first electrode; arranging a second substrate, on which a light emitting element is arranged, on the conductive bonding pattern, wherein the light emitting element comprises a contact electrode arranged on one surface, and wherein an adhesive layer is on one surface of the second substrate; and bonding the light emitting element using the conductive bonding pattern by irradiating the adhesive layer with a laser beam by a laser irradiator and pressing the light emitting element with the conductive bonding pattern by pressing a pressing member in a direction in which the conductive bonding pattern is arranged on the second substrate, wherein a height of the reflective partition wall is based on a height of the light emitting element, a depth at which the light emitting element is embedded in the conductive bonding pattern, and a depth at which the light emitting element is embedded in the adhesive layer of the second substrate.

According to one or more embodiments, the height of the reflective partition wall is a length of the height of the light emitting element excluding a depth at which the light emitting element is embedded in the adhesive layer of the second substrate and a depth at which the light emitting element is embedded in the conductive bonding pattern.

According to one or more embodiments, the height of the light emitting element is a body length of the light emitting element and a thickness of the contact electrode, wherein the body length of the light emitting element is a distance from a top surface of the light emitting element to an interface between the light emitting element and the contact electrode.

According to one or more embodiments, in the forming the conductive bonding pattern, wherein a top surface of the conductive bonding pattern is flat on the same layer as a top surface of the via layer.

According to one or more embodiments, the forming the via layer on the first substrate, and the forming the reflective partition wall on the via layer comprising: forming a via material layer on an entire surface of the first substrate to cover the first electrode; forming an organic layer including a first opening area on the via material layer; forming a reflective film on the organic layer to form the reflective partition wall; and etching a portion of the via material layer to form the via layer so that at least a portion of the first electrode is exposed.

According to one or more embodiments, before the forming the reflective partition wall by forming the reflective film on the organic layer, wherein a first protective layer is formed on the organic layer, wherein a second protective layer is formed on the reflective film after the forming the reflective film on the organic layer.

According to one or more embodiments, the conductive bonding pattern comprises a polymer resin and conductive nanoparticles dispersed in the polymer resin.

According to one or more embodiments, the conductive nanoparticles are conductive carbon black.

According to one or more embodiments, the light emitting element comprises: a first semiconductor layer doped with a first conductive dopant; a second semiconductor layer doped with a second conductive dopant; an active layer arranged between the first semiconductor layer and the second semiconductor layer; a protective film arranged on side surfaces of the first semiconductor layer, the active layer, and the second semiconductor layer; and the contact electrode arranged on a bottom surface of the first semiconductor layer.

According to one or more embodiments, the contact electrode comprises a first contact electrode and a second contact electrode.

According to one or more embodiments, in forming the first electrode on the first substrate, wherein a second electrode is formed spaced from the first electrode when the first electrode is formed on the first substrate.

According to one or more embodiments, a top surface of the light emitting elements has a concave-convex structure having a cross-sectional shape of a semicircle or a semi-ellipse.

According to one or more embodiments, the concave-convex structure is embedded in the adhesive layer of the second substrate.

According to one or more embodiments, the method further comprising separating the second substrate from the light emitting element.

According to one or more embodiments, a method for manufacturing an electronic device comprising a display device, the method comprising: forming a first electrode on a first substrate; forming a reflective partition wall on the first substrate; forming a conductive bonding pattern on the first electrode; arranging a second substrate, on which a light emitting element is arranged, on the conductive bonding pattern, wherein the light emitting element comprises a contact electrode arranged on one surface, and wherein an adhesive layer is on one surface of the second substrate; and bonding the light emitting element using the conductive bonding pattern by irradiating the adhesive layer with a laser beam by a laser irradiator and pressing the light emitting element with the conductive bonding pattern by pressing a pressing member in a direction in which the conductive bonding pattern is arranged on the second substrate, wherein a height of the reflective partition wall is based on a height of the light emitting element, a depth at which the light emitting element is embedded in the conductive bonding pattern, a depth at which the light emitting element is embedded in the adhesive layer of the second substrate, a height of the first electrode, and a height of the conductive bonding pattern.

According to one or more embodiments, a height of the reflective partition wall is a length excluding a depth at which the light emitting element is embedded in the adhesive layer of the second substrate and a depth at which the light emitting element is embedded in the conductive bonding pattern from a height of the light emitting element, a height of the first electrode, and a height of the conductive bonding pattern.

According to one or more embodiments, the conductive bonding pattern comprises a polymer resin and conductive nanoparticles dispersed in the polymer resin.

According to one or more embodiments, the conductive nanoparticles are conductive carbon black.

According to one or more embodiments, a top surface of the light emitting elements has a concave-convex structure having a cross-sectional shape of a semicircle or a semi-ellipse, wherein the concave-convex structure is embedded in the adhesive layer of the second substrate.

According to one or more embodiments, the method further comprising separating the second substrate from the light emitting elements.

According to the display device and its manufacturing method according to the embodiments, bonding failure of a light emitting element may be reduced or prevented.

The reduction of bonding failure may be advantageous in terms of cost.

Panel image quality and defects may be improved due to reduced bonding failure.

However, the effects, aspects, and features of the present disclosure are not limited to the aforementioned effects, aspects, and features, and various other effects, aspects, and features are included in the present specification.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is a layout drawing illustrating pixels of a display area according to one or more embodiments.

FIG. 6 is a cross-sectional view illustrating one example of a cross-section of a display panel corresponding to the line I1-I1′ in FIG. 5.

FIG. 7 is a cross-sectional view illustrating one example of an area A of FIG. 6 in detail.

FIG. 8 is a cross-sectional view illustrating one example of the area A of FIG. 6 in detail according to one or more embodiments.

FIG. 9 is a layout diagram illustrating pixels of a display area according to one or more embodiments.

FIG. 10 is a cross-sectional view illustrating one example of a cross-section of a display panel corresponding to the line I2-I2′ of FIG. 9.

FIG. 11 is a cross-sectional view illustrating one example of an area B of FIG. 10 in detail.

FIG. 12 and FIG. 13 are cross-sectional views illustrating one example of the area B of FIG. 10 in detail according to one or more embodiments.

FIG. 14 is a flowchart illustrating a manufacturing method of a display device according to one or more embodiments.

FIG. 15-FIG. 23 are cross-sectional views of manufacturing steps of a display device according to one or more embodiments.

FIGS. 24 and 25 are example drawings illustrating a smart watch including a display device according to one or more embodiments.

FIG. 26 is an exploded perspective view of a smart watch including a display device according to one or more embodiments.

FIG. 27 is an example views of a virtual reality (VR) device including a display device according to one or more embodiments.

FIG. 28 is an example view of a VR device including a display device according to one or more embodiments.

FIG. 29 is an example view illustrating a vehicle instrument cluster and center fascia including display devices according to one or more embodiments.

FIG. 30 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

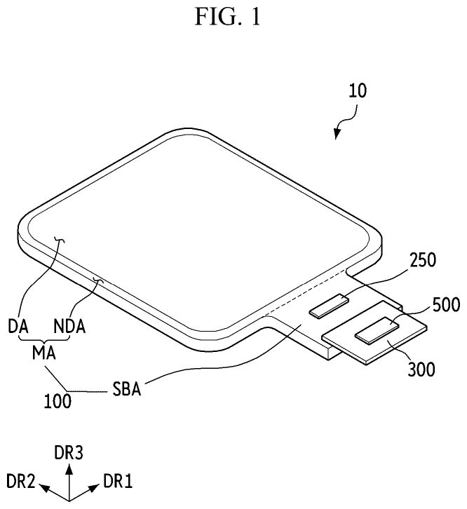

FIG. 1 is a perspective view illustrating a display device according to one or more embodiments.

Referring to FIG. 1, the display device 10 is a device for displaying video and/or still images, and may be a mobile phone, a smart phone, a tablet personal computer, and a portable electronic device such as a smart watch, a watch phone, a mobile communication terminal, an electronic notebook, an e-book, portable electronic devices such as portable multimedia players (PMP), navigation systems, ultra mobile PC (UMPC), and/or the like, as well as a variety of electronic devices such as televisions, laptops, monitors, billboards, internet of things (IOT) devices, and/or the like, which may be included and used as display screens. Also, the display device 10 may be included in other electronic devices such as a virtual reality (VR) device or an augmented reality (AR) device and used to display an image in the electronic devices. In one or more embodiments, an electronic device including the display device 10 may further include a display device storage portion in which the display device 10 is stored, and/or a case or cover for protecting the display device 10.

In one or more embodiments, the display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, hereinafter, an ultra-small light emitting diode is described as a light emitting element for convenience of explanation.

The display device 10 includes a display panel 100, a display driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, but may be formed in other polygonal, circular, or oval shapes. The display panel 100 may be formed flat but is not limited thereto. In one example, the display panel 100 may be formed at the left and right ends and may include curved portions with a constant curvature or a changing curvature. In addition, the display panel 100 may be flexibly formed to be bent, curved, bent, folded, and/or rolled.

The display panel 100 may include the main area MA and the sub-area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits light of a first color (or first light), a second sub-pixel that emits light of a second color (or second light), and a third sub-pixel that emits light of a third color (or third light), but the present disclosure is not limited thereto.

The sub-area SBA may protrude from one side of the main area MA in a second direction DR2 (e.g., in the longitudinal direction of the display panel 100). In FIG. 1, the sub-area SBA is illustrated as being unfolded, but the sub-area SBA may be bent, in which case it may be arranged on the bottom surface of the display panel 100. When the sub-area SBA is bent, it may overlap the main area MA in a third direction DR3, which is the thickness direction of the display panel 100. A display driving circuit 250 may be arranged in the sub-area SBA.

The display driving circuit 250 may generate signals and voltages for driving the display panel 100. The display driving circuit 250 may be formed as an integrated circuit (IC) and attached to the indication panel 100 using a chip on glass (COG) method, a chip on plastic (COP) method, or an ultrasonic bonding method but is not limited thereto. In one or more embodiments, the display driving circuit 250 may be attached to the circuit substrate 300 using a chip on film (COF) method.

The circuit substrate 300 may be attached to one end of the sub-area SBA of the display panel 100. As such, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate a plurality of panel driving voltages according to an external power supply voltage. The power supply circuit 500 may be formed as an integrated circuit (IC) and attached to the circuit substrate 300 using a COF method.

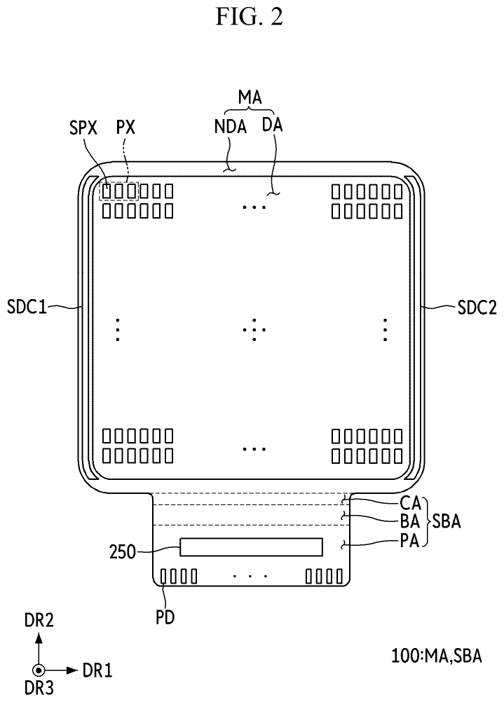

FIG. 2 is a layout diagram (e.g., a plan view drawing) illustrating a display panel according to one or more embodiments. FIG. 2 illustrates that the sub-area SBA is unfolded without being bent.

Referring to FIGS. 1 and 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA includes pixels PX for displaying an image, and each pixel PX may include a plurality of sub-pixels SPX. A pixel PX may be defined as a sub-pixel group that is the smallest unit capable of expressing white gradation (e.g., a white gray level).

The non-display area NDA may be arranged adjacent to the display area DA. The non-display area NDA may be an area outside the display area DA. The non-display area NDA may be arranged to be around (e.g., to surround) the display area DA. The non-display area NDA may be an edge area of the display panel 100.

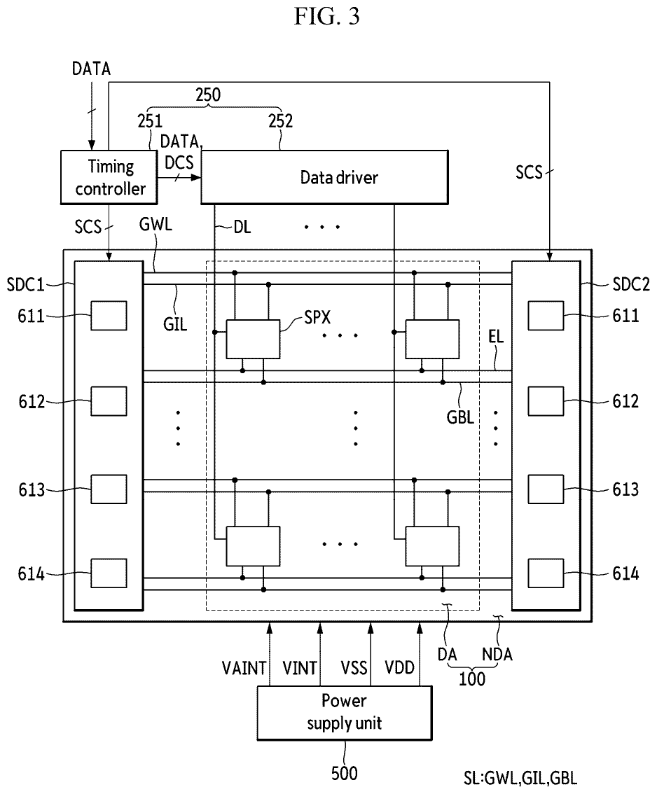

A first scan driving portion SDC1 and a second scan driving portion SDC2 may be arranged in a non-display area NDA. The first scan driving portion SDC1 may be arranged on one side (e.g., the left side) of the display panel 100, and second scan driving portion SDC2 may be arranged on the other side (e.g., the right side) of the display panel, but is not limited thereto. Each of the first scan driving portion SDC1 and the second scan driving portion SDC2 may be electrically connected to a display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines. The configuration and operation of the first scan driving portion SDC1 and the second scan driving portion SDC2 will be described in detail with reference to FIGS. 3-7.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub area SBA may be less than the length in the first direction DR1 of the main area MA or may be substantially equal to the length in the first direction DR1 of the main area MA. The sub-area SBA may be curved and arranged below the main area MA. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are arranged. The display driving circuit 250 may be attached to the driving pads of the pad area PA using a conductive adhesive member such as an anisotropic conductive film. The circuit substrate 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be arranged below the connection area CA and below the main area MA. The bending area BA may be arranged between the connection area CA and the pad area PA. One side of the bending area BA may be in contact with the connection area CA, and the other side of the bending area BA may be in contact with the pad area PA.

FIG. 3 is a block drawing illustrating a display device according to one or more embodiments.

The pixels PX may be arranged along the first direction DR1 and the second direction DR2. For example, the pixels PX may be arranged in a matrix form along the first direction DR1 and the second direction DR2. For example, the plurality of pixels PX may be arranged along rows and columns of a matrix along the first direction DR1 and the second direction DR2. The scan lines SL and the first light emitting control lines EL may extend in the first direction DR1 and be arranged or placed along the second direction DR2. The data lines DL may extend in the second direction DR2 and may be arranged or placed along the first direction DR1. The scan lines SL may include write scan lines GWL, initialization scan lines GIL, and bias scan lines GBL. The configuration or number of the scan lines SL may vary depending on the structure or driving method of the pixels PX. In one or more embodiments, the scan lines SL may also include a plurality of control scan lines GCL.

Each of the pixels PX may include a plurality of sub-pixels SPX. For example, each of the pixels PX may include a first sub-pixel SPX1, a second sub-pixel SPX2, and a third sub-pixel SPX3. The first sub-pixel SPX1, the second sub-pixel SPX2, and the third sub-pixel SPX3 may emit light of a first color, light of a second color, and light of a third color, respectively. The light of the first color, light of the second color, and light of the third color may be, but are not limited to, red light (e.g., light in a red wavelength band having a main peak wavelength of about 600 nm to 750 nm), green light (e.g., light in a green wavelength band having a main peak wavelength of about 480 nm to 560 nm), and blue light (e.g., light in a blue wavelength band having a main peak wavelength of about 370 nm to 460 nm), respectively. In one or more embodiments, the first sub-pixel SPX1, the second sub-pixel SPX2, and the third sub-pixel SPX3 of each of the pixels PX may be arranged in the first direction DR1. The number, type, arrangement structure, and/or light emitting wavelength of the sub-pixels SPX included in each of the pixels PX may be variously changed according to embodiments.

Each of the plurality of sub-pixels SPX may be connected to one of the write scan lines GWL, one of the initialization scan lines GIL, one of the bias scan lines GBL, one of the light emitting control lines EL, and one of the data lines DL. In one or more embodiments, each of the plurality of sub-pixels SPX may also be connected to a control scan line GCL from among the plurality of control scan lines GCL. In describing the embodiments, the term “connection” may include the meaning of “physical connection” and/or “electrical connection.”

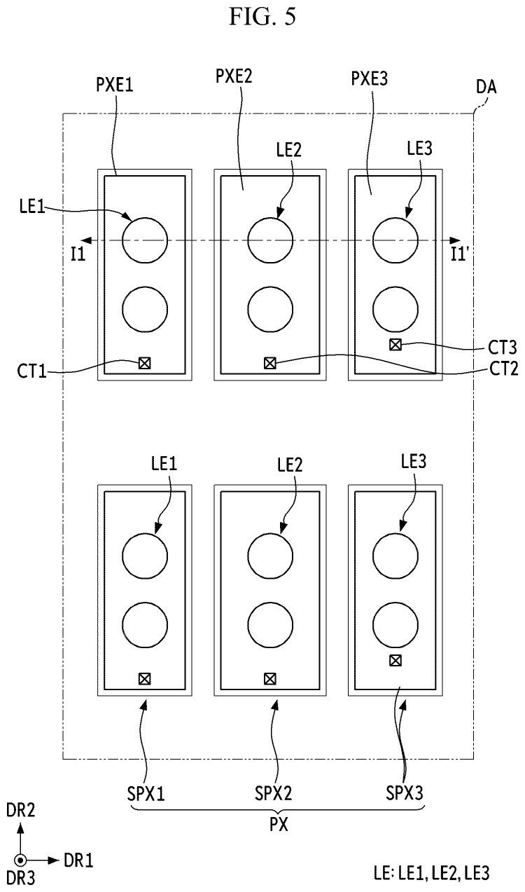

Each of the plurality of sub-pixels SPX may be supplied with a data voltage of a data line DL according to a write scan signal of a write scan line GWL and may emit light from a light emitting element according to the data voltage. The plurality of sub-pixels SPX included in each pixel PX may be connected to different data lines DL. For example, the first sub-pixel SPX1, the second sub-pixel SPX2, and the third sub-pixel SPX3 (e.g., see FIG. 5) may be connected to a first data line DLr, a second data line DLg, and a third data line DLb, respectively, of the data lines DL. Accordingly, the light-emitting luminance of each of the first sub-pixel SPX1, the second sub-pixel SPX2, and the third sub-pixel SPX3 may be individually controlled.

In one or more embodiments, each of the pixels PX is connected to two or

more light emitting control lines EL, and the light emitting periods (or on-duty ratios) of at least two sub-pixels SPX among the plurality of sub-pixels SPX included in each pixel PX may be independently and/or individually controlled by different light emitting control signals supplied to the different light emitting control lines EL. For example, in one or more embodiments, the light emitting control lines EL may include a first light emitting control line EL1 and a second light emitting control line EL2, and in each horizontal line (e.g., each pixel row) of the display area DA, a first light emitting control line EL1 and a second light emitting control line EL2 may be arranged, which are connected to different sub-pixels SPX among the sub-pixels SPX included in the pixels PX arranged in the corresponding horizontal line. For example, in one or more embodiments, the first light emitting control line EL1 may be connected to the first sub-pixels SPX1 of the pixels PX arranged in the corresponding horizontal line, and the second light emitting control line EL2 may be connected to the second sub-pixels SPX2 and the third sub-pixels SPX3 included in the pixels PX of the corresponding horizontal line.

The first scan driving portion SDC1, the second scan driving portion SDC2, and a display driving circuit 250 may be arranged in the non-display area NDA.

Each of the first scan driving portion SDC1 and the second scan driving portion SDC2 may include a write scan signal output portion 611, an initialization scan signal output portion 612, a bias scan signal output portion 613, and an emission control signal output portion 614.

In one or more embodiments, the emission control signal output portion 614 may include a first light emitting driver and a second light emitting driver.

In one or more embodiments, the first light emitting driver may be connected to the first light emitting control line EL1. The second light emitting driver may be connected to the second light emitting control line EL2.

In one or more embodiments, the first sub-pixel SPX1 may emit light during a first light emitting period in response to a first light emitting control signal supplied through the first light emitting control line EL1. The first light emitting period may be a period during which a driving current may flow to the first sub-pixel SPX1 by the first light emitting control signal. The second sub-pixel SPX2 and the third sub-pixel SPX3 may emit light during a second light emitting period in response to a second light emitting control signal supplied through the second light emitting control line EL2. The second light emitting period may be a period during which a driving current may flow to the second sub-pixel SPX2 and the third sub-pixel SPX3 by the second light emitting control signal. The first light emitting period and the second light emitting period may be controlled independently or separately from each other and may or may not temporally overlap each other.

In one or more embodiments, the duration of the first light emitting period and the duration of the second light emitting period may be different. For example, the duration of the first light emitting period may correspond to an on-duty ratio adjusted so that the first sub-pixel SPX1 emits light with a target luminance according to a driving current optimized for the light emitting efficiency of the first sub-pixel SPX1 (e.g., a driving current within a range in which the light emitting element of the first sub-pixel SPX1 exhibits optimal consumption efficiency).

The duration of the second light emitting period may correspond to an on-duty ratio adjusted so that the second sub-pixel SPX2 and the third sub-pixel SPX3 emit light with a target luminance at a driving current optimized for the light emitting efficiency of the second sub-pixel SPX2 and the third sub-pixel SPX3 (e.g., a driving current within a range where the light emitting elements of the second sub-pixel SPX2 and the third sub-pixel SPX3 exhibit optimal consumption efficiency).

Each of the first scan driving portion SDC1 and the second scan driving portion SDC2 may be electrically connected to the pixels PX through scan lines SL. For example, each of the first scan driving portion SDC1 and the second scan driving portion SDC2 may be electrically connected to pixel circuits of the sub-pixels SPX included in each pixel PX through write scan lines GWL, initialization scan lines GIL, and bias scan lines GBL.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit (e.g., a timing controller) 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL.

The emission control signal output portion 614 may generate emission control signals according to the scan timing control signal SCS and sequentially output them to the emission control lines EL. When the sub-pixels SPX of each horizontal line are divided and connected to a plurality of light emitting control lines EL (e.g., the first light emitting control line EL1 and the second light emitting control line EL2 of each horizontal line), emission control signal output portion 614 may output each light emitting control signal to the plurality of light emitting control lines EL for each horizontal period.

The display driving circuit 250 may include a timing control circuit (e.g., a timing controller) 251 and a data driving circuit (e.g., a data driver) 252.

The data driving circuit 252 may be electrically connected to the pixels PX through the data lines DL. For example, the data driving circuit 252 may be electrically connected to the pixel circuits of the sub-pixels SPX included in each pixel PX through the first data line DLr, the second data line DLg, and the third data line DLb.

The data driving circuit 252 may receive digital video data DATA and a data timing control signal DCS from the timing control circuit 251. The data driving circuit 252 converts the digital video data DATA into analog data voltages according to the data timing control signal DCS and outputs the converted data to the data lines DL. In this case, the sub-pixels SPX are selected by the write scan signal of the first scan driving unit SDC1 and the second scan driving unit SDC2, and the selected sub-pixels.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 251 may output the scan timing control signal SCS to the first scan driving unit SDC1 and the second scan driving unit SDC2. The timing control circuit 251 may output digital video data DATA and a data timing control signal DCS to the data driving circuit 252.

The power supply circuit (e.g., the power supply unit) 500 may generate panel driving voltages according to a power voltage supplied from the outside. For example, the power supply circuit 500 may generate a first driving voltage VDD, a second driving voltage VSS, a third driving voltage VINT, and a fourth driving voltage VAINT, and supply them to the display panel 100. In one or more embodiments, the power supply circuit 500 may also generate a fifth driving voltage VOBS. The first driving voltage VDD, the second driving voltage VSS, the third driving voltage VINT, and the fourth driving voltage VAINT, are supplied to the sub-pixels SPX through respective power supply lines connected between the power supply circuit 500 and the sub-pixels SPX and may be used to drive the sub-pixels SPX. Depending on the structure or operation method of the sub-pixels SPX, the number and/or types of panel driving voltages output from the power supply circuit 500 may change.

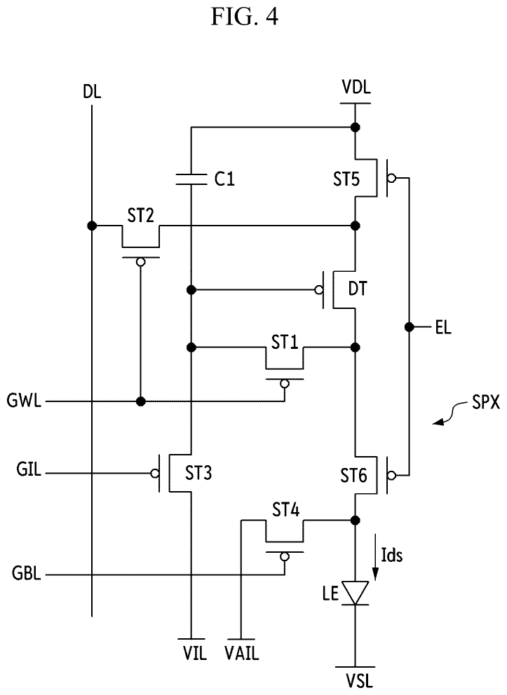

FIG. 4 is an equivalent circuit diagram illustrating a sub-pixel according to one or more embodiments.

Referring to FIG. 4, a sub-pixel SPX according to one or more embodiments may be connected to scan lines GWL, GIL, and GBL, an emission control line EL, and a data line DL. For example, the sub-pixel SPX may be connected to a write scan line GWL, an initialization scan line GIL, a bias scan line GBL, an emission control line EL, and a data line DL.

The sub-pixel SPX according to one or more embodiments includes a driving transistor DT, switching elements, a capacitor C1, and a lighting element LE. The switching elements include first to sixth transistors ST1, ST2, ST3, ST4, ST5, and ST6.

The driving transistor DT includes a gate electrode, a first electrode, and a second electrode. The driving transistor DT controls a drain-source current (Ids, hereinafter referred to as “driving current”) flowing between the first electrode and the second electrode according to a data voltage applied to a gate electrode of the driving transistor DT.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power supply voltage is applied.

A capacitor C1 is formed between the gate electrode of a driving transistor DT and a first power supply line VDL to which a first power supply voltage is applied. The first power supply voltage may be a voltage of a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, they may be turned on when a scan signal of a gate low voltage and an emission control signal of a gate low voltage are applied to the initialization scan line GIL, the write scan line GWL, the bias scan line GBL, and the emission line EL, respectively. One electrode of the third transistor ST3 may be connected to the first initialization voltage line VIL to which the third power supply voltage (e.g., the third driving voltage VINT of FIG. 3) is applied, and one electrode of the fourth transistor ST4 may be connected to the second initialization voltage line VAIL to which the fourth power supply voltage (e.g., the fourth driving voltage VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage (e.g., the first driving voltage VDD) and at a higher level than the second power supply voltage (e.g., the second driving voltage VSS).

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. In this case, the active layers of each of the driving transistor DT, the second transistor ST2, the fourth transistor ST4, the fifth transistor ST5, and the sixth transistor ST6 formed of p-type MOSFETs are formed of polysilicon, the active layers of each of the first transistor ST1 and the third transistor ST3 formed of an n-type MOSFET may be formed of an oxide semiconductor. Furthermore, because the first transistor ST1 and the third transistor ST3 are formed as n-type MOSFET, the first transistor ST1 may be turned on when a write scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as p-type MOSFET, so they may be turned on when a scan signal of the gate low voltage and a light emission control signal of a gate low voltage are applied.

Alternatively, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on when a scan signal of a gate high voltage is applied, whereas the remaining transistors DT, ST1, ST2, ST3, ST5, and ST6 may be turned on when a scan signal of a gate low voltage and a light emission control signal of a gate low voltage are applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT is formed of an oxide semiconductor and may be turned on when a scan signal of a gate high voltage and a light emission control signal are applied.

In general, semiconductor light emitting elements (hereinafter, micro LED) with a diameter or major axis length of several to several hundred micrometers tend to have lower external quantum efficiency EQE than light emitting elements of relatively large sizes. The external quantum efficiency may generally mean the number of photons generated relative to the injected carriers. In particular, the carrier leakage may be severe at low currents in the early stages of operation, which may result in a decrease in the luminance of the element.

In one or more embodiments, the external quantum efficiency of the red-light emitting element R is significantly lower than that of the blue-light emitting element B or the green-light emitting element G. Also, even in the optimal current density range that produces the optimal external quantum efficiency, the red-light emitting element R is significantly lower than that of the blue-light emitting element B or the green-light emitting element G.

The on-duty ratio of a light emitting element that generally emits a red wavelength is low, whereas the on-duty ratio of a light emitting element that emits a blue wavelength or a green wavelength may be relatively high. Nevertheless, when the on-duty ratios of the light emitting element that emits a red wavelength and the light emitting element that emits a blue wavelength or a green wavelength are identically reflected, the light emitting element that emits a red wavelength uses a low current density section, which increases power consumption. Therefore, in one or more embodiments, the light emitting control signals that control the light emitting element that emits a red wavelength and the light emitting control signals that control the light emitting element that emits a blue wavelength or a green wavelength are separately operated by applying the first light emitting driver and the second light emitting driver of the emission control signal output portion 614, thereby reducing power consumption.

FIG. 5 is a layout drawing illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels, the three sub-pixels may be the first sub-pixel SPX1, the second sub-pixel SPX2, and the third sub-pixel SPX3 may include.

The plurality of pixels PX may be arranged in a matrix form. In each of the plurality of pixels PX, the first sub-pixel SPX1, the second sub-pixel SPX2, and the third sub-pixel SPX3 may be arranged along a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. The light of the first color may be red as light of the first wavelength band, the light of the second color may be green as light of the second wavelength band, and the light of the third color may be blue as light of the third wavelength band. For example, the third wavelength band of blue light may have a main peak wavelength of the light included in a wavelength band from approximately 370 μm to 460 μm, the second wavelength band of green light may have a main peak wavelength of the light included in a wavelength band from approximately 480 μm to 560 μm, and the first wavelength band of red light may have a main peak wavelength of the light included in a wavelength band from approximately 600 μm to 750 μm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1 and a plurality of first light emitting elements LE1. The second sub-pixel SPX2 includes a second pixel electrode PXE2 and a plurality of second light emitting elements LE2. The third sub-pixel SPX3 includes a third pixel electrode PXE3 and a plurality of third light emitting elements LE3.

The light emitting element LE1 of the first sub-pixel SPX1 may emit light of a first color, the light emitting element LE2 of the second sub-pixel SPX2 may emit light of a second color, and the light emitting element LE3 of the third sub-pixel SPX3 may emit light of a third color.

Each of the first pixel electrode PXE1, the second pixel electrode PXE2, and the third pixel electrode PXE3 may have a rectangular planar shape having a short side in a first direction DR1 and a long side in a second direction DR2. The area of the first sub-pixel SPX1, the area of the second sub-pixel SPX2, and the area of the third sub-pixel SPX3 may be set according to the light-emitting efficiency of the light emitting element LE included in each sub-pixel SPX. For example, the area of the sub-pixel may be larger as the light conversion efficiency is lower.

For example, when the light-emitting efficiency of the second light emitting element LE2 of the second sub-pixel SPX2 is lower than the light-emitting efficiency of the first light emitting element LE1 of the first sub-pixel SPX1 and the third light emitting element LE3 of the third sub-pixel SPX3, the area of the second pixel electrode PXE2 may be larger than the area of the first pixel electrode PXE1 and larger than the area of the third pixel electrode PXE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

A plurality of light emitting elements LE may be arranged on each of the pixel electrodes PXE1, PXE2, and PXE3. The same number of light emitting elements LE may be arranged on each of the pixel electrodes PXE1, PXE2, and PXE3. For example, two light emitting elements LE may be arranged on each of the pixel electrodes PXE1, PXE2, and PXE3.

Each of the plurality of light emitting elements LE may have a circular planar shape, but the present disclosure is not limited thereto. For example, each of the plurality of light emitting elements LE may have a rectangular planar shape.

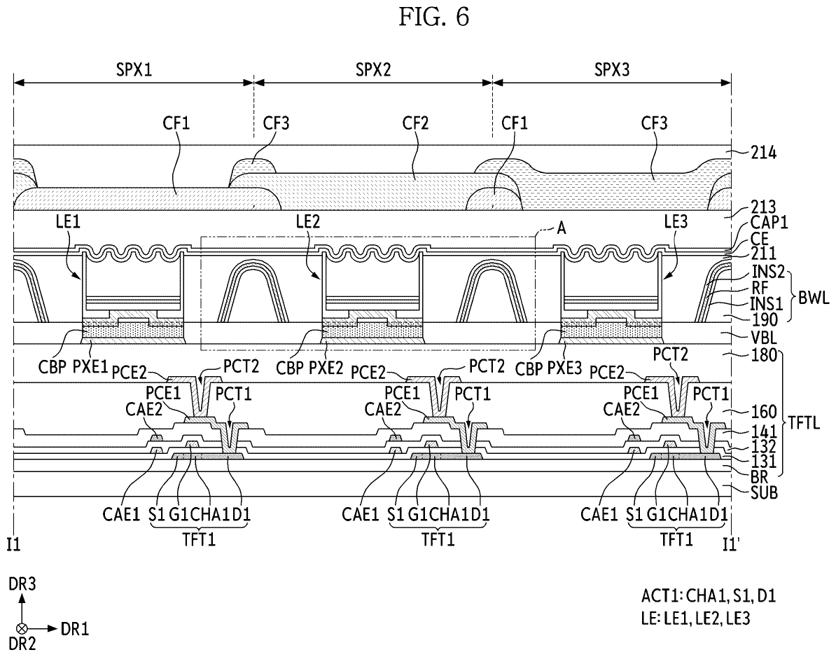

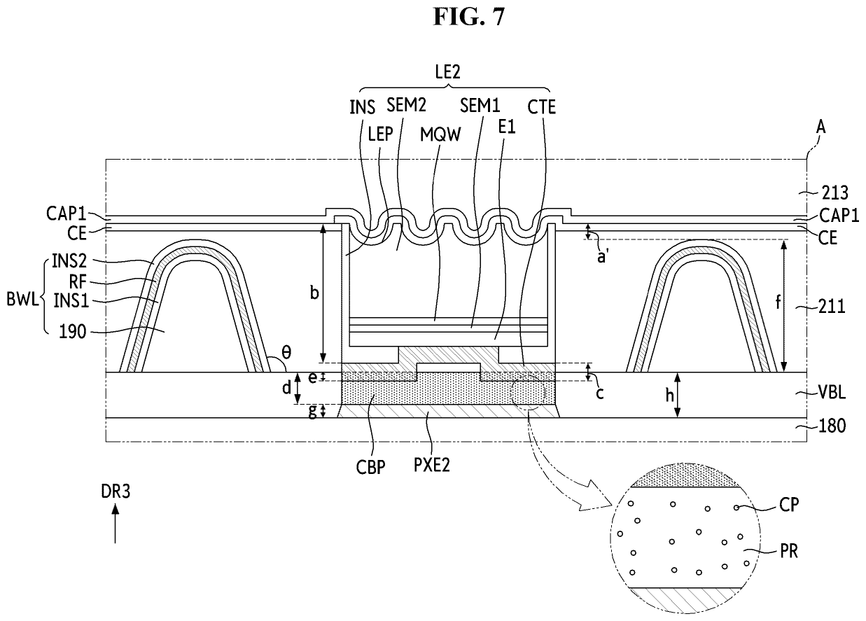

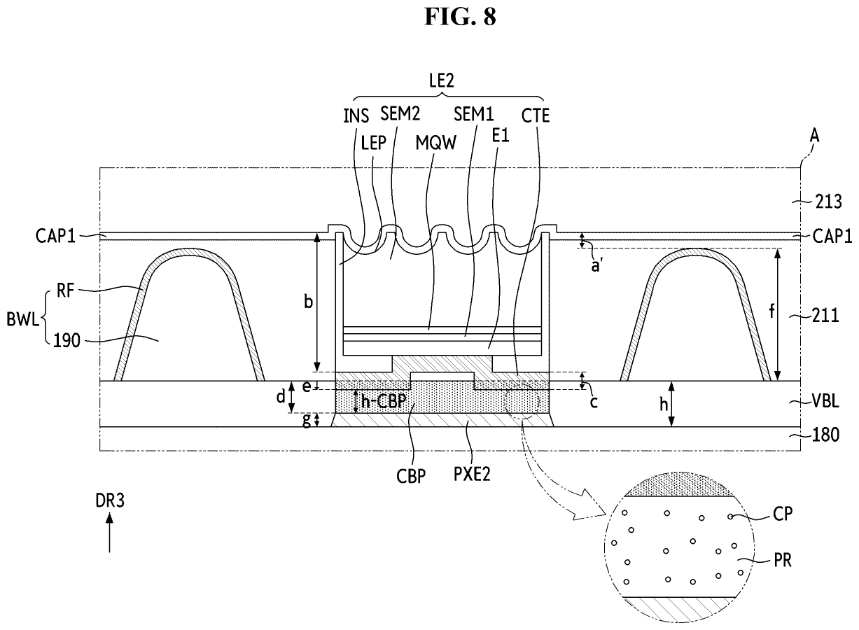

FIG. 6 is a cross-sectional view illustrating one example of a cross-section of a display panel corresponding to the line I1-I1′ in FIG. 5. FIG. 7 is a cross-sectional view illustrating one example of an area A of FIG. 6 in detail. FIG. 8 is a cross-sectional view illustrating one example of the area A of FIG. 6 in detail according to one or more embodiments.

Referring to FIGS. 6 and 7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be arranged on the substrate SUB. The barrier film BR is a film that protects a thin-film transistor layer TFTL from moisture penetrating through the substrate SUB which is vulnerable to moisture permeation. The barrier film BR may be formed of a plurality of inorganic films that are alternately stacked.

A thin-film transistor TFT1 may be arranged on the barrier film BR. The thin-film transistor TFT1 may be either the fourth transistor ST4 or the sixth transistor ST6 shown in FIG. 4. The thin-film transistor TFT1 may include a first active layer ACT1 and a first gate electrode G1.

The first active layer ACT1 of the thin-film transistor TFT1 may be arranged on the barrier film BR. The first active layer ACT1 of the thin-film transistor TFT1 may include polycrystalline silicon, monocrystalline silicon, low-temperature polycrystalline silicon, and/or amorphous silicon. Alternatively, the first active layer ACT1 of the thin-film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin-film transistor TFT1 and on the barrier film BR.

A first gate metal layer may be arranged on the first gate insulating film 131. The first gate metal layer may include a first gate electrode G1 of a thin-film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged spaced from (e.g., spaced apart from) each other in FIG. 6, the first gate electrode G1 and the first capacitor electrode CAE1 may be connected to each other.

A second gate insulating film 132 may be arranged on the first gate electrode G1 and the first capacitor electrode CAE1 of the thin-film transistor TFT1 and on the first gate insulating film 131.

A second gate metal layer may be arranged on the second gate insulating film 132. The second gate metal layer may include a second capacitor electrode CAE2. The second capacitor electrode CAE2 may overlap the first capacitor electrode CAE1 of the thin-film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2 and on the second gate insulating film 132.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be arranged on the first source connection electrode PCE1 and on the first interlayer insulating film 141 to planarize a step caused by the thin-film transistor TFT1.

A second data metal layer may be arranged on the first planarization organic film 160. The second data metal layer may include a second source connection electrode PCE2. The second source connection electrode PCE2 may be connected to the first source connection electrode PCE1 through a second pixel contact hole PCT2 penetrating the first planarization organic film 160.

A second planarization organic film 180 may be arranged on the second source connection electrode PCE2 and on the first planarization organic film 160.

The barrier film BR, the first gate insulating film 131, the second gate insulating film 132, and the interlayer insulating film 141 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic insulating film such as an acrylic resin, an epoxy resin, a phenolic resin, a polyamide resin, and/or a polyimide resin.

A light emitting element layer may be arranged on the second planarization organic film 180. The light emitting element layer may include pixel electrodes PXE1, PXE2, and PXE3, a conductive bonding pattern CBP, light emitting elements LE, a common electrode CE, a via layer VBL, and a reflective partition wall BWL.

A pixel electrode layer and a via layer VBL may be arranged on the second planarization organic film 180. The pixel electrode layer may include a first pixel electrode PXE1, a second pixel electrode PXE2, and a third pixel electrode PXE3. Each of the pixel electrodes PXE1, PXE2, and PXE3 may be connected to a second source connection electrode PCE2 through a connection hole (CT1/CT2/CT3 of FIG. 5) penetrating the second planarization organic film 180. Each of the pixel electrodes PXE1, PXE2, and PXE3 may be connected to a first source area S1 or a first drain area D1 of a thin-film transistor TFT1 through the first source connection electrode PCE1 and the second source connection electrode PCE2. Thus, a voltage controlled by the thin-film transistor TFT1 may be applied to each of the pixel electrodes PXE1, PXE2, and PXE3.

The pixel electrodes PXE1, PXE2, and PXE3 may be formed of a single layer or multiple layers made of one or an alloy of molybdenum (Mo), aluminum (Al), chromium (Cr), gold (Au), titanium (Ti), nickel (Ni), neodymium (Nd), and/or copper (Cu). For example, the pixel electrode layer may be made of copper (Cu) having low surface resistance to lower the resistance of each of the pixel electrodes PXE1, PXE2, and PXE3. Further, the pixel electrodes PXE1, PXE2, and PXE3 may include a first layer made of one or an alloy of molybdenum (Mo), aluminum (Al), chromium (Cr), gold (Au), titanium (Ti), nickel (Ni), neodymium (Nd), and/or copper (Cu) at the bottom, and a second layer made of a metal material having a high reflectivity, such as aluminum (Al), on the first layer, when the pixel electrodes PXE1, PXE2, and PXE3 are formed in a multilayer structure.

The light emitting elements LE may be arranged on the pixel electrodes PXE1, PXE2, and PXE3. For example, a first light emitting element LE1 may be arranged on the first pixel electrode PXE1. A second light emitting element LE2 may be arranged on the second pixel electrode PXE2. A third light emitting element LE3 may be arranged on the third pixel electrode PXE3.

The conductive bonding pattern CBP may be arranged on one surface of each of the first pixel electrode PXE1, the second pixel electrode PXE2, and the third pixel electrode PXE3.

The thickness (height) of the conductive bonding pattern CBP, that is, the distance h-CBP between the interface between the conductive bonding pattern CBP and the corresponding pixel electrode PXE1, PXE2, and PXE3 and the interface between the conductive bonding pattern CBP and the corresponding light emitting element LE (e.g., the contact electrode CTE) is about 1 μm or less.

The light emitting elements LE may be bonded to and electrically connected to the corresponding pixel electrodes PXE1, PXE2, and PXE3 by the conductive bonding pattern CBP.

The conductive bonding pattern CBP may be a conductive bonding pattern including conductive nanoparticles CP. The conductive bonding pattern CBP may include a polymer resin and conductive nanoparticles CP dispersed in the polymer resin. The conductive nanoparticles CP are conductive particles having a particle size of 100 μm or less. The resistance of the conductive nanoparticles CP is 1 ohm or less.

The conductive nanoparticle CP may be, but is not limited to, conductive carbon black. In addition to carbon black, the conductive nanoparticle CP may include at least one of the first materials selected from the group consisting of acetylene black, artificial graphite, natural graphite, copper powder, nickel powder, aluminum powder, indium powder, silver powder, and polyphenylene.

The conductive bonding pattern CBP may be melted at less than 200° C., for example, at 140° C., to bond the light emitting elements LE to the corresponding pixel electrodes PXE1, PXE2, and PXE3.

The polymer resin may be an acrylic resin or a polyimide resin. The conductive bonding pattern CBP may be patterned by a photolithography process. Thus, the conductive bonding pattern CBP may also be finely patterned and may be applied to a high-brightness display panel.

The via layer VBL is arranged on the second planarization organic film 180, and the top surface of the via layer VBL may be parallel to the top surface of the conductive bonding pattern CBP.

In one or more embodiments, the via layer VBL may cover a portion of the pixel electrodes PXE1, PXE2, and PXE3. The via layer VBL may cover the pixel electrodes PXE1, PXE2, and PXE3 that are not covered by the conductive bonding pattern CBP.

The via layer VBL may be formed of an organic film such as an acrylic resin, an epoxy resin, a phenolic resin, a polyamide resin, a polyimide resin, and/or the like.

The reflective partition wall BWL may be formed on the via layer VBL at a first inclination angle θ and a first height f. The first inclination angle θ may be about 120 to 135 degrees.

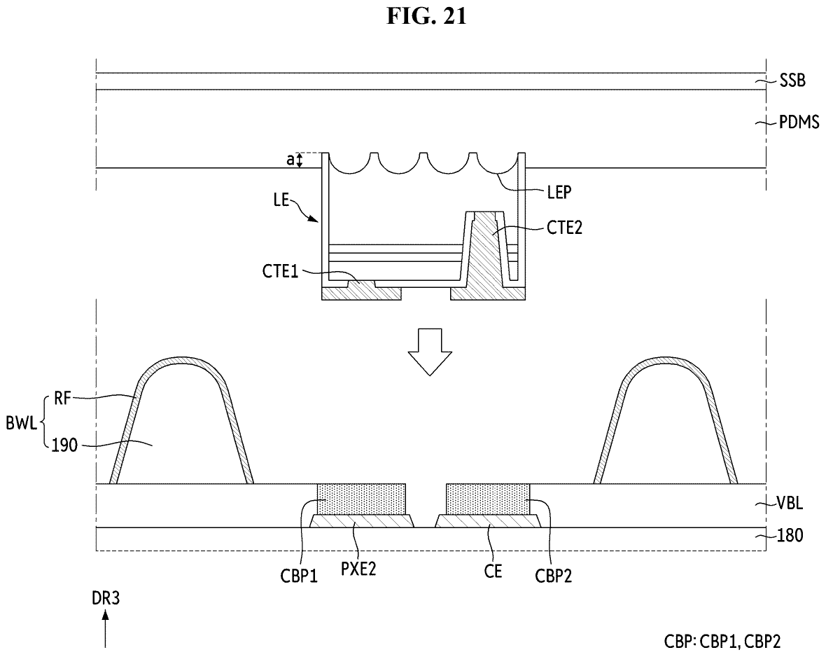

The first height f of the reflective partition wall BWL may be set based on the body length b of the light emitting element LE, the depth at which the light emitting element LE is embedded in the adhesive layer of the relay substrate (SSB in FIG. 21), and the depth e at which the light emitting element LE is embedded in the conductive bonding pattern CBP. In one or more embodiments, the height, depth, and thickness refer to the length in the vertical direction (the third direction, DR3) from the substrate. The body length b of the light emitting element LE may be the height minus the thickness c of the contact electrode CTE from the total height of the light emitting element LE. On the other hand, the depth at which the light emitting element LE is embedded in the adhesive layer of the relay substrate (SSB in FIG. 21) may be equal to or shorter than the distance a′ between the top surface of the light emitting element LE and the top surface of the reflective partition wall BWL.

The height h of the via layer VBL may be equal to the height g of the pixel electrode PXE2 and the height d of the conductive bonding pattern CBP.

The distance h of the height h of the conductive bonding pattern CBP minus the depth e of embedding in the conductive bonding pattern CBP becomes the distance h-CBP between the conductive bonding pattern CBP and the contact electrode CTE. The distance h-CBP between the conductive bonding pattern CBP and the contact electrode CTE should be about 1 μm or less. If the distance h-CBP between the conductive bonding pattern CBP and the contact electrode CTE is about 1 μm or more, the conductivity may be reduced.

The depth of embedding in the adhesive layer of the relay substrate (SSB in FIG. 21) and the depth e at which the light emitting element LE is embedded in the conductive bonding pattern CBP will be described later with reference to FIG. 21.

The reflective partition wall BWL surrounds the light emitting element LE on a plane. Thus, even if the light emitting element LE does not have a separate reflective film, the light emitted from the side of the light emitting element LE may be reflected to the front by the reflective partition wall BWL, thereby improving the light emission efficiency of the display panel 100. Therefore, the higher the reflective partition wall BWL, the more suitable it may be in terms of light emission efficiency. However, if the reflective partition wall BWL is longer than a suitable length (e.g., a predetermined length), it may cause a bonding failure in the bonding process of the light emitting element LE. Therefore, the appropriate height of the reflective partition wall BWL may be the highest height that may be formed without causing a bonding failure of the light emitting element LE in the bonding process.

In one or more embodiments, the reflective partition wall BWL may include a first organic layer 190 defining the shape of the partition wall, a first protective film INS1 covering the first organic layer 190, a reflective film RF covering the first protective film INS1, and a second protective film INS2 covering reflective film RF.

The first organic layer 190 may be formed of an organic material such as an acrylic resin, an epoxy resin, a phenolic resin, a polyamide resin, a polyimide resin, and/or the like.

The first protective film INS1 is arranged outside the first organic layer 190. The first protective film INS1 may cover the entire first organic layer 190.

The reflective film RF is arranged outside the first protective film INS1.

The second protective film INS2 is arranged on top of the reflective film RF. The reflective film RF is surrounded by the first protective film INS1 and the second protective film INS2.

The reflective film RF may be spaced (e.g., spaced apart) from the light emitting element LE in a plane and may have a closed loop shape that surrounds the sides of the light emitting element LE. The upper end of the reflective film RF may be arranged higher than the active layer MQW of the light emitting element LE. The lower end of the reflective film RF may be positioned lower than the conductive layer E1 of the light emitting element LE. The reflective film RF may include a metal material having a high reflectivity, such as aluminum (Al).

The reflective film RF may reflect light traveling in a lateral direction from the light emitting element LE and emit light to the top surface of the light emitting element LE. Therefore, because the light loss of the light emitting element LE may be reduced, the light efficiency of the light emitting element LE may be increased.

The inclination of the reflective film RF is the same as the inclination θ of the reflective partition wall BWL. As the inclination θ increases, the front light emission efficiency may increase. However, as the inclination θ of the reflective film RF increases, the width of the first organic layer 190 may increase. Therefore, it may be preferable that the inclination θ of the reflective film RF be about 120° to 130°.

The first protective film INS1 and the second protective film INS2 may be formed of an inorganic film, such as silicon nitride (SiNₓ), silicon oxide nitride (SiON), silicon oxide (SiOₓ), titanium oxide (TiOₓ), or aluminum oxide (AlOₓ).

In one or more embodiments, at least one layer of the first protective layer INS1 or the second protective layer INS2 may be omitted. For example, as shown in FIG. 8, both the first protective layer INS1 and the second protective layer INS2 may be omitted.

A plurality of light emitting elements LE may be arranged on a conductive bonding pattern CBP. In FIGS. 6-8, each of the plurality of light emitting elements LE is shown as a vertical type micro LED extending in the third direction DR3. The vertical type micro LED refers to an LED having a structure in which a first semiconductor layer SEM1, an active layer MQW, and a second semiconductor layer SEM2 are sequentially arranged along the third direction DR3, which is a vertical direction.

The light emitting element LE may include a substantially vertical side surface as shown in FIG. 8. For example, the light emitting element LE may be patterned through vertical etching and may have a rectangular or square cross-sectional shape in which the width of the top surface and the width of the bottom surface are substantially the same. The shape of the light emitting element LE may be variously changed according to embodiments. For example, the light emitting element LE may have an inverted taper cross-sectional shape. For example, the light emitting element LE may have an inverted trapezoidal cross-sectional shape in which the width of the top surface is wider than the width of the bottom surface.

Each of the plurality of light emitting elements LE may be formed of an inorganic material such as gallium nitride (GaN). Each of the plurality of light emitting elements LE may have a length in the first direction DR1, a length in the second direction DR2, and a length in the third direction DR3 of several to several hundred μm, respectively. For example, each of the plurality of light emitting elements LE may have a length in the first direction DR1, a length in the second direction DR2, and a length in the third direction DR3 of approximately 3 μm to 10 μm or less.

Each of the plurality of light emitting elements LE may be grown and formed on a semiconductor substrate, such as a silicon substrate or a sapphire substrate. The plurality of light emitting elements LE may be transferred directly from the semiconductor substrate onto the conductive bonding pattern CBP of the display panel 100. Alternatively, the plurality of light emitting elements LE may be transferred onto the conductive bonding pattern CBP of the display panel 100 through an electrostatic method using an electrostatic head or a stamp method using an elastic polymer material such as PDMS or silicon as a transfer substrate.

The light emitting element LE may include a conductive layer E1, a first semiconductor layer SEM1, an active layer MQW, a second semiconductor layer SEM2, a contact electrode CTE, and a protective layer INS.

The conductive layer E1 may be arranged on the bottom surface of the first semiconductor layer SEM1. In FIG. 7, the conductive layer E1 is illustrated as covering the entire bottom surface of the first semiconductor layer SEM1, but the present disclosure is not limited thereto. For example, the conductive layer E1 may be arranged on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be arranged on the conductive layer E1. The first semiconductor layer SEM1 may be formed of a semiconductor material layer doped with a first conductive dopant such as magnesium (Mg), zinc (Zn), calcium (Ca), strontium (Sr), barium (Ba), etc., for example, gallium nitride (GaN).

The active layer MQW may be arranged on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) and/or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to Group V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The second semiconductor layer SEM2 may be arranged on the active layer MQW. The second semiconductor layer SEM2 may be a semiconductor material layer doped with a second conductivity type dopant such as silicon (Si), germanium (Ge), tin (Sn), etc., for example, gallium nitride (GaN).

An electron blocking layer may be arranged between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The light emitting element LE may further include light extracting patterns LEP arranged on a top surface. For example, the light extracting patterns LEP may be formed on a top surface of the second semiconductor layer SEM2.

The light extraction patterns LEP may be patterns for increasing the efficiency of light emitted from the top surface of the light emitting element LE. The light extraction pattern LEP may be a concave-convex pattern formed in a hemisphere or a semi-ellipse. The light extraction pattern LEP may be a concave-convex pattern having a cross-sectional shape of a semicircle or a semi-ellipse.

The protective film INS may be a film for protecting the bottom surface and the side surface of the light emitting element LE. The protective film INS may be arranged on the bottom surface and the side surface of the conductive layer E1 and the side surface of the semiconductor stack. Specifically, the protective film INS may be arranged on the bottom surface and the side surface of the conductive layer E1, the side surface of the first semiconductor layer SEM1, the side surface of the active layer MQW, and the side surface of the second semiconductor layer SEM2. The protective film INS may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The contact electrode CTE may be arranged on the protective film INS. The contact electrode CTE may be arranged between the pixel electrodes PXE1, PXE2, and PXE3 and the protective film INS. The contact electrode CTE may be in contact with the pixel electrodes PXE1, PXE2, and PXE3 (e.g., the contact electrode CTE may be in contact with the pixel electrodes PXE1, PXE2, and PXE3 via the conductive bonding pattern CBP).

The contact electrode CTE may be connected to the exposed conductive layer E1 that is not covered by the protective film INS.

The contact electrode CTE may include indium (In), bismuth (Bi), molybdenum (Mo), aluminum (Al), chromium (Cr), gold (Au), titanium (Ti), nickel (Ni), neodymium (Nd), copper (Cu), and/or and tin-silver-copper alloy (Sn—Ag—Cu). Specifically, the plurality of contact electrode CTE may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The second organic layer 211 may be arranged to cover the side surfaces of the plurality of light emitting elements LE.

The second organic layer 211 is a layer for flattening the steps caused by the plurality of light emitting elements LE. The height of the second organic layer 211 may be arranged to cover most of the side surfaces of each of the plurality of light emitting elements LE, but in another embodiment, it may be arranged to cover the side surfaces of each of the light emitting elements LE by a plurality of organic films.

The second organic layer 211 may be formed of an organic film such as an acrylic resin, epoxy resin, phenolic resin, polyamide resin, polyimide resin, and/or the like.

A common electrode CE may be arranged on the top surface of each of the plurality of light emitting elements LE and the top surface of the second organic layer 211.

The common electrode CE may be a common layer formed commonly on the first sub-pixel SPX1, the second sub-pixel SPX2, and the third sub-pixel SPX3. For example, the common electrode CE may be arranged on the first light emitting element LE1, the second light emitting element LE2, and the third light emitting element LE31. The common electrode CE may be made of a transparent conductive material (TCO) such as indium tin oxide (ITO) and/or indium zinc oxide (IZO) that may transmit light.

The pixel electrodes PXE1, PXE2, and PXE3 may be referred to as an anode electrode or a first electrode, and the common electrode CE may be referred to as a cathode electrode or a second electrode.

A first capping layer CAP1 may be arranged on the common electrode CE. The first capping layer CAP1 may serve to encapsulate a lower component.

The first capping layer CAP1 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A third organic layer 213 may be disposed on the first capping layer CAP1. A plurality of color filters CF1, CF2, and CF3 may be arranged on the third organic layer 213. The plurality of color filters CF1, CF2, and CF3 may include first color filters CF1, second color filters CF2, and third color filters CF3.

The first color filter CF1 arranged on the first sub-pixel SPX1 may transmit first light (e.g., light in a red wavelength band). Therefore, the first sub-pixel SPX1 may emit the first light (e.g., light in the red wavelength band).

The second color filter CF2 arranged in the second sub-pixel SPX2 may transmit the second light (e.g., light in the green wavelength band). Therefore, the second sub-pixel SPX2 may emit the second light (e.g., light in the green wavelength band).

The third color filter CF3 arranged in the third sub-pixel SPX3 may transmit the third light (e.g., light in the blue wavelength band). Therefore, the third sub-pixel SPX3 may emit the third light (e.g., light in the blue wavelength band).

The first color filter CF1, the second color filter CF2, and the third color filter CF3 overlapping in the third direction DR3 may overlap the reflective partition wall BWL in the third direction DR3. In another embodiment, the first color filter CF1, the second color filter CF2, and the third color filter CF3 may be omitted.

A fourth organic layer 214 for planarization may be placed on a plurality of color filters CF1, CF2, and CF3.

The third organic layer 213 and the fourth organic layer 214 may be formed from an acrylic resin, an epoxy resin, a phenolic resin, a polyamide resin, a polyimide resin, and/or the like.

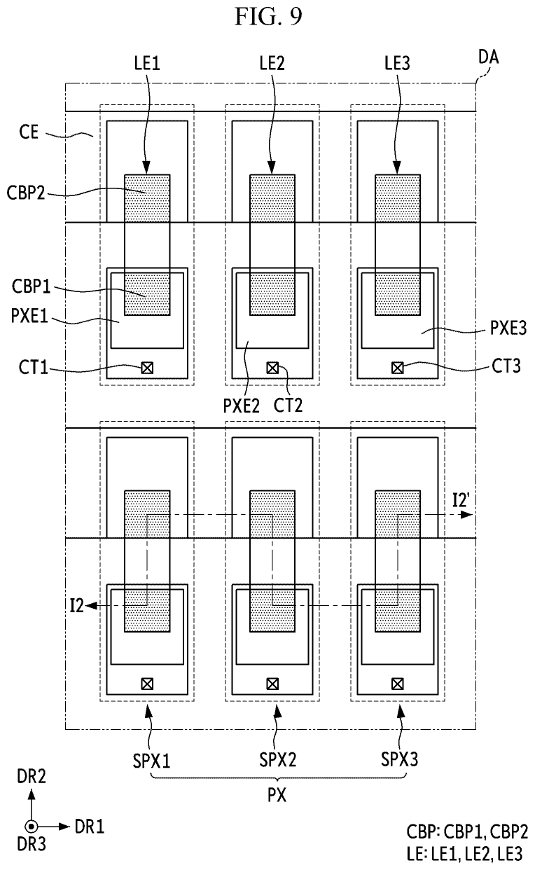

FIG. 9 is a layout diagram illustrating pixels of a display area according to one or more embodiments.

The embodiment of FIG. 9 differs from the embodiment of FIG. 6 in that the light emitting element LE is arranged on the pixel electrodes PXE1, PXE2, and PXE3 and the common electrode CE in each of the first sub-pixel SPX1, the second sub-pixel SPX2, and the third sub-pixel SPX3. In FIG. 9, descriptions that overlap with the embodiment of FIG. 6 will be omitted, and differences from the embodiment of FIG. 6 will be mainly described.

Referring to FIG. 9, each of the sub-pixels SPX1, SPX2, and SPX may include the pixel electrodes PXE1, PXE2, and PXE3, the common electrode CE, the light emitting element LE, and the conductive bonding pattern CBP.

The pixel electrodes PXE1, PXE2, and PXE3 and the common electrode CE in each of the first sub-pixel SPX1, the second sub-pixel SPX2, and the third sub-pixel SPX3 may be arranged along the second direction DR2. Each of the pixel electrodes PXE1, PXE2, and PXE3 and the common electrodes CE may have a rectangular planar shape, but the present disclosure is not limited thereto.

The common electrode CE may be connected to a second power supply line VSL to which a second driving voltage VSS is applied. Thus, the second driving voltage VSS may be applied to each of the common electrodes CE.

In each of the first sub-pixel SPX1, the second sub-pixel SPX2, and the third sub-pixel SPX3, the light emitting elements LE are arranged on the pixel electrodes PXE1, PXE2, and PXE3 and the common electrode CE, so that the length of the light emitting element LE in the second direction DR2 may be longer than the length in the first direction DR1.

The conductive bonding pattern CBP is arranged on the first pixel electrode PXE1 and the common electrode CE. In one or more embodiments, a first conductive bonding pattern CBP1 may be arranged on pixel electrodes PXE1, PXE2, and PXE3. The second conductive bonding pattern CBP2 may be arranged on the common electrode CE. The conductive bonding pattern CBP may have a rectangular flat shape but is not limited thereto.

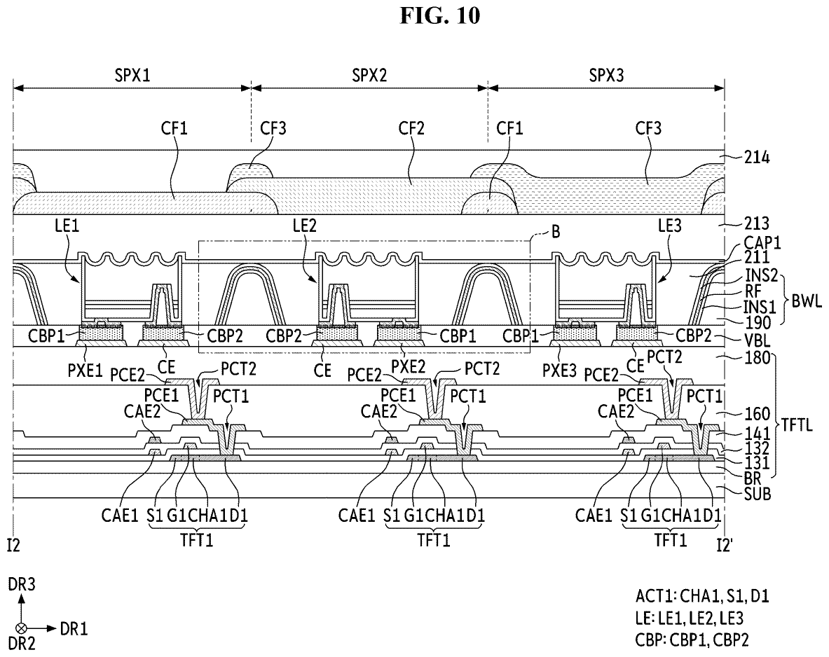

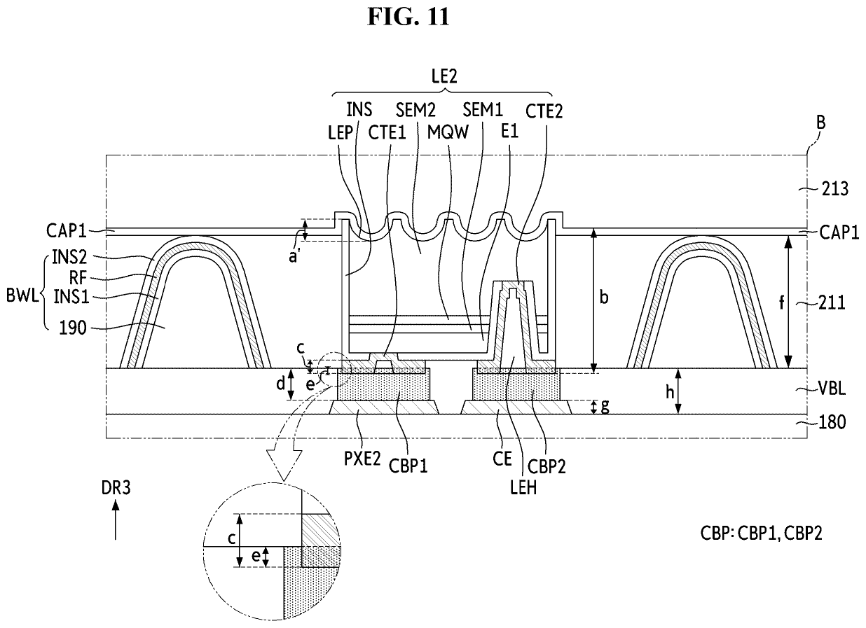

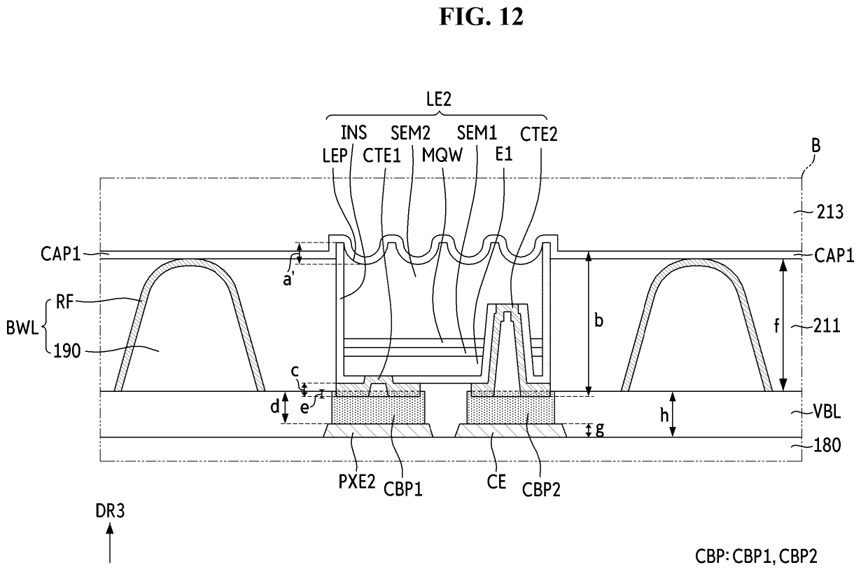

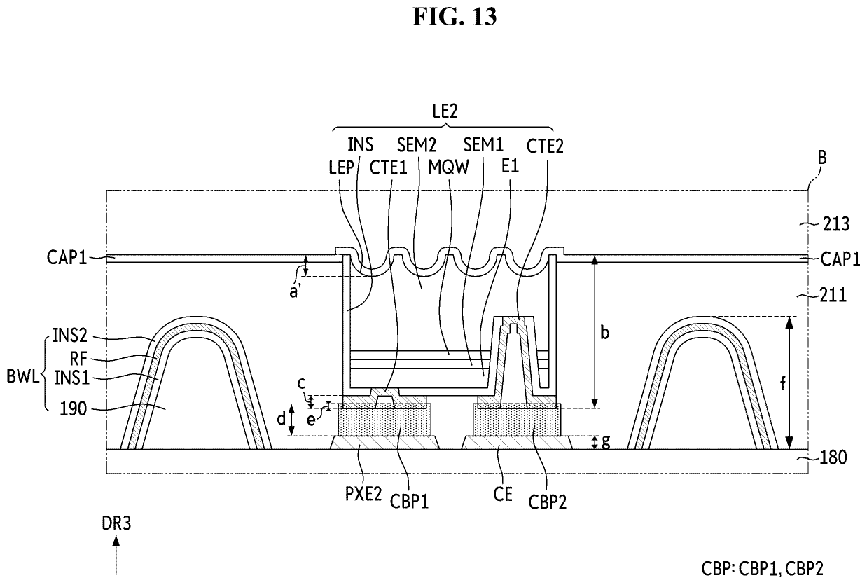

FIG. 10 is a cross-sectional view illustrating one example of a cross-section of a display panel corresponding to the line I2-I2′ of FIG. 9. FIG. 11 is a cross-sectional view illustrating one example of an area B of FIG. 10 in detail. FIG. 12 and FIG. 13 are cross-sectional views illustrating one example of the area B of FIG. 10 in detail according to another embodiment.

The embodiments of FIGS. 10 and 11 differ from the embodiments of FIGS. 6 and 7 in that the light emitting element LE is a flip-type micro LED and a common electrode CE is arranged on the same layer as the pixel electrode PXE. In FIGS. 10 and 11, descriptions that overlap with the embodiments of FIGS. 6 and 7 will be omitted, and differences from the embodiments of FIGS. 6 and 7 will be mainly described.

Referring to FIGS. 10 and 11, a pixel electrode layer including pixel electrodes PXE1, PXE2, and PXE3 and a common electrode CE may be arranged on a second planarization organic film 180.

A via layer VBL is arranged on the second planarization organic film 180, and the top surface of the via layer VBL and the top surface of the conductive bonding pattern CBP are arranged at the same height.

In one or more embodiments, the via layer VBL may cover edges of the pixel electrodes PXE1, PXE2, and PXE3 and the common electrode CE. The via layer VBL may cover the pixel electrodes PXE1, PXE2, and PXE3 that are not covered by the conductive bonding pattern CBP.

The via layer VBL may be formed of an organic film such as an acrylic resin, an epoxy resin, a phenolic resin, a polyamide resin, a polyimide resin, and/or the like.

The conductive bonding pattern CBP may include a first conductive bonding pattern CBP1 and a second conductive bonding pattern CBP2. The first conductive bonding pattern CBP1 and the second conductive bonding pattern CBP2 may include a polymer resin PR and conductive nanoparticles CP dispersed in the polymer resin PR.

The conductive nanoparticles CP may be conductive carbon black but are not limited thereto. In addition to carbon black, the conductive nanoparticles CP may include at least one first material selected from the group consisting of acetylene black, artificial graphite, natural graphite, copper powder, nickel powder, aluminum powder, indium powder, silver powder, and polyphenylene.

The polymer resin PR may be an acrylic-based resin, a polyimide-based resin, or the like.

The first conductive bonding pattern CBP1 may be arranged on pixel electrodes PXE1, PXE2, and PXE3, and the second conductive bonding pattern CBP2 may be arranged on the common electrode CE. The light emitting element LE may be arranged on the first conductive bonding pattern CBP1 and the second conductive bonding pattern CBP2.

The light emitting element LE may be a flip-type micro LED. The flip-type micro LED refers to an LED in which contact electrodes CTE1 and CTE2 are formed on one surface (e.g., the bottom surface) of the light emitting element LE. The length in the third direction DR3 of the plurality of light emitting elements LE may be approximately 3 μm to 5 μm or less but is not limited thereto.

While FIG. 11 illustrates an example where the INS is arranged on the sides of the conductive layer E1, the sides of the first semiconductor layer SEM1, the sides of the active layer MQW, and the sides of the second semiconductor layer SEM2, the present disclosure are not limited thereto. In one example, the insulating layer INS may be arranged on the sides of the first semiconductor layer SEM1, the sides of the active layer MQW, and the sides of the second semiconductor layer SEM2.

The plurality of light emitting elements LE may be arranged on the pixel electrodes PXE1, PXE2, and PXE3 and the common electrode CE.

A first contact electrode CTE1 may be arranged on the pixel electrodes PXE1, PXE2, and PXE3, and a second contact electrode CTE2 may be arranged on the common electrode CE.

A hole LEH may be formed to penetrate the conductive layer E1, the first semiconductor layer SEM1, and the active layer MQW of the light emitting element LE to expose the second semiconductor layer SEM2. The hole LEH may have a circular planar shape, but the present disclosure is not limited thereto. For example, the hole LEH may have a polygonal planar shape, such as an oval or a square. The conductive layer E1, the first semiconductor layer SEM1, the active layer MQW, and the second semiconductor layer SEM2 of the first light emitting element LE1 have been described with reference to FIGS. 6 and 7, and thus detailed descriptions thereof will not be repeated. The conductive layer E1, the first semiconductor layer SEM1, the active layer MQW, and the second semiconductor layer SEM2 of the second light emitting element LE2 and the third light emitting element LE3 have been described with reference to FIGS. 6 and 7, and thus detailed descriptions thereof will not be repeated.

Further, the protective film INS may be arranged on the sidewall of the conductive layer E1 exposed in the hole LEH, the sidewall of the first semiconductor layer SEM1, the sidewall of the active layer MQW, and the sidewall of the second semiconductor layer SEM2. The protective film INS may not cover the second semiconductor layer SEM2 in the hole LEH.

The first contact electrode CTE1 may be arranged on one surface of the conductive layer E1. Thus, the first contact electrode CTE1 may be electrically connected to the conductive layer E1 that is not cover by the protective film INS and exposed.

In FIG. 11, the second contact electrode CTE2 may be arranged on one surface of the conductive layer E1 spaced (e.g., spaced apart) from the first contact electrode CTE1. The second contact electrode CTE2 may be arranged on the protective film INS arranged in the hole LEH and the second semiconductor layer SEM2 exposed in the hole LEH without being covered by the protective film INS. Thus, the second contact electrode CTE2 may be electrically connected to the second semiconductor layer SEM2 in the hole LEH. The first contact electrode CTE1 and the second contact electrode CTE2 may include indium (In), bismuth (Bi), molybdenum (Mo), aluminum (Al), chromium (Cr), gold (Au), titanium (Ti), nickel (Ni), neodymium (Nd), copper (Cu), and/or a tin-silver-copper alloy (Sn—Ag—Cu) (SAC). Specifically, the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

In another variation, for example, the second contact electrode CTE2 may fill the inside of the hole LEH. That is, the second contact electrode CTE2 may be in the shape of a column.

The first contact electrode CTE1 and the second contact electrode CTE2 protrude in a vertical direction from one side of the protective film INS to the substrate. The length protruding from one side of the protective film INS is referred to as the thickness C of the first contact electrode CTE1 and the second contact electrode CTE2.

At least a portion of the first contact electrode CTE1 and the second contact electrode CTE2 may be embedded within the conductive bonding pattern CBP. For example, the first contact electrode CTE1 may be partially embedded in the first conductive bonding pattern CBP1, and the second contact electrode CTE2 may be partially embedded in the second conductive bonding pattern CBP1.

The height h of the via layer VBL may be equal to the height g of the pixel electrode PXE2 and the height d of the conductive bonding pattern CBP.

The distance d of the height of the conductive bonding pattern CBP minus the depth e of embedding in the conductive bonding pattern CBP becomes the distance between the conductive bonding pattern CBP and the contact electrode CTE. The distance between the conductive bonding pattern CBP and the contact electrode CTE should be about 1 μm or less. If the distance between the conductive bonding pattern CBP and the contact electrode CTE is about 1 μm or more, the conductivity may be reduced.

The reflective partition wall BWL may be formed at a first height f with a first inclination angle θ on the via layer VBL.

The first inclination angle θ may be about 120 degrees to 135 degrees. The height f of the reflective partition wall BWL may be formed based on the body length b of the light emitting element LE, the depth at which the light emitting element LE is embedded in the adhesive layer (PDMS in FIG. 21) of the relay substrate (SSB in FIG. 21), and the depth e at which the light emitting element LE is embedded in the conductive bonding pattern CBP. For example, the height f of the reflective partition wall BWL is equal to the sum of the body length b of the light emitting element LE and the thickness c of the contact electrode CTE minus the depth at which the light emitting element LE is embedded in the adhesive layer of the relay substrate (SSB in FIG. 21) and the depth e at which the light emitting element LE is embedded in the conductive bonding pattern CBP. The height f of the reflective partition wall BWL may be expressed as in mathematical expression 1.

Height (f) of reflective partition wall BWL=body length (b) of light emitting element LE+thickness (c) of contact electrode CTE−depth at which light emitting element LE is embedded in the adhesive layer of the relay substrate (SSB in FIG. 21)−depth (e) at which light emitting element LE is embedded in the conductive bonding pattern CBP. Mathematical expression 1:

Here, the sum of the body length b of the light emitting element LE and the thickness c of the contact electrode CTE may be the total height of the light emitting element LE. The light-emitting element LE may be a portion of the light emitting element LE excluding the contact electrode CTE. For example, the body length b of the light emitting element LE may be the distance from the top of the light emitting element LE to the interface between the light emitting element LE and the contact electrode CTE. On the other hand, the depth at which the light emitting element LE is embedded in the adhesive layer of the relay substrate (SSB in FIG. 21) may be equal to or shorter than the distance a′ between the top surface of the light emitting element LE and the top surface of the reflective partition wall BWL.

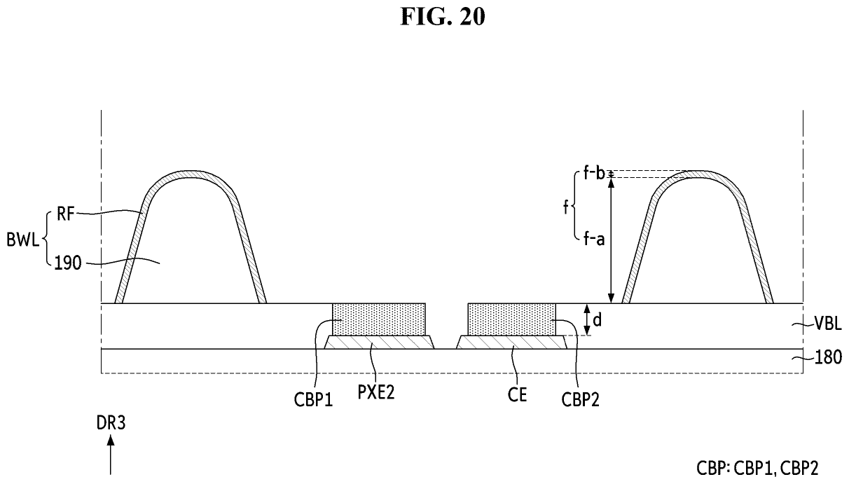

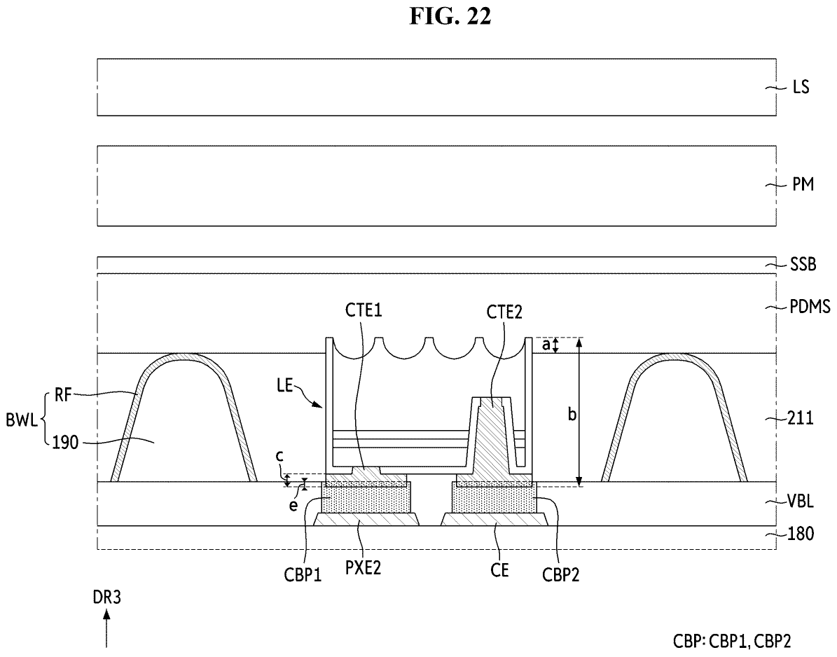

The thickness (height) of the reflective partition wall BWL will be described in detail with reference to FIGS. 20 and 22.

The reflective partition wall BWL surrounds the light emitting element LE on a plane. Thus, even when the light emitting element LE does not have a separate reflective film, the light emitted from the side of the light emitting element LE may be reflected to the front by the reflective partition wall BWL, thereby improving the light emission efficiency of the display panel 100.

The reflective partition wall BWL may include a first organic layer 190 defining the shape of the partition wall, a first protective film INS1 covering the first organic layer 190, a reflective film RF, and a second protective film INS2.

The first organic layer 190 may be formed of an organic material, such as an acrylic resin, an epoxy resin, a phenolic resin, a polyamide resin, a polyimide resin, and/or the like.

The first protective film INS1 is arranged outside the first organic layer 190. The first protective film INS1 may cover the entire first organic layer 190.

The reflective film RF is arranged outside the first protective film INS1.

The second protective film INS2 is arranged on top of the reflective film RF. The reflective film RF is surrounded by the first protective film INS1 and the second protective film INS2.

The reflective film RF may be a closed loop shape that is spaced (e.g., spaced apart) from the light emitting element LE on a plane and surrounds the side of the light emitting element LE. The top of the reflective film RF may be positioned higher than the active layer MQW of the light emitting element LE. The bottom of the reflective film RF may be positioned lower than the light emitting element LE. The reflective film RF may include a metal material having high reflectivity, such as aluminum (Al).

The reflective film RF may reflect light traveling in a lateral direction from the light emitting element LE and emit (e.g., redirect) light to the top surface of the light emitting element LE. Therefore, because the loss of light from the light emitting element LE may be reduced, the light efficiency of the light emitting element LE may be increased.

The front light emission efficiency may increase as the inclination θ of the reflective film RF increases, but the width of the first organic layer 190 may increase as the inclination θ of the reflective film RF increases. Therefore, the inclination θ of the reflective film RF may be preferably about 120° to 130°.

The first protective layer INS1 and the second protective layer INS2 may be formed of an inorganic layer such as silicon nitride (SiNₓ), silicon oxide nitride (SiON), silicon oxide (SiOₓ), titanium oxide (TiOₓ), or aluminum oxide (AlOₓ).

In another embodiment, at least one layer of the first protective layer INS1 or the second protective layer INS2 may be omitted. For example, as shown in FIG. 12, both the first protective layer INS1 and the second protective layer INS2 may be omitted.

In another embodiment, referring to FIG. 13, the via layer VBL may be omitted.

When the via layer VBL is omitted, the reflective partition wall BWL may be arranged on the second planarization organic layer 180.

In this case, the height f of the reflective partition wall BWL when the via layer VBL is omitted may be based on the body length b of the light emitting element LE, the depth at which the light emitting element LE is embedded in the adhesive layer of the relay substrate (SSB in FIG. 21), the depth e at which the light emitting element LE is embedded in the conductive bonding pattern CBP, the thickness c of the contact electrode CTE, the height d of the conductive bonding pattern CBP, and the height g of the pixel electrode PXE2. For example, the height f of the reflective partition wall BWL is equal to the sum of the body length b of the light emitting element LE, the thickness c of the contact electrode CTE, the height d of the conductive bonding pattern CBP, and the height g of the pixel electrode PXE2, minus the depth at which the light emitting element LE is embedded in the adhesive layer of the relay substrate (SSB in FIG. 21) and the depth e at which the light emitting element LE is embedded in the conductive bonding pattern CBP. The height f of the reflective partition wall BWL may be expressed as in mathematical expression 2.

Height of reflective partition wall BWL (f)=body length of light emitting element LE (b)+thickness of contact electrode CTE (c)+height of conductive bonding pattern CBP (d)+height of pixel electrode PXE2 (g)−depth of light emitting element LE embedded in adhesive layer of relay substrate (SSB in FIG. 21)−depth of light emitting element LE embedded in conductive bonding pattern CBP (e). Mathematical expression 2:

On the other hand, the depth of light emitting element LE embedded in adhesive layer of relay substrate (SSB in FIG. 21) may be equal to or shorter than the distance a′ between the top surface of light emitting element LE and the top surface of reflective partition wall BWL (e.g., see FIG. 12).

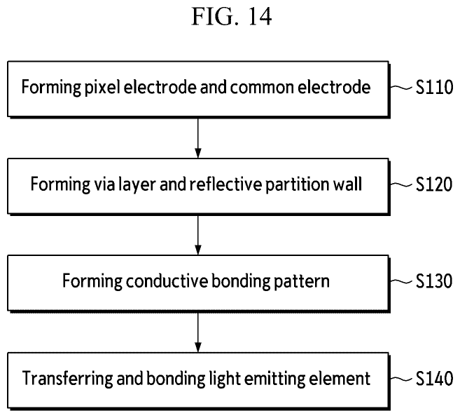

FIG. 14 is a flowchart illustrating a manufacturing method of a display device according to one or more embodiments.

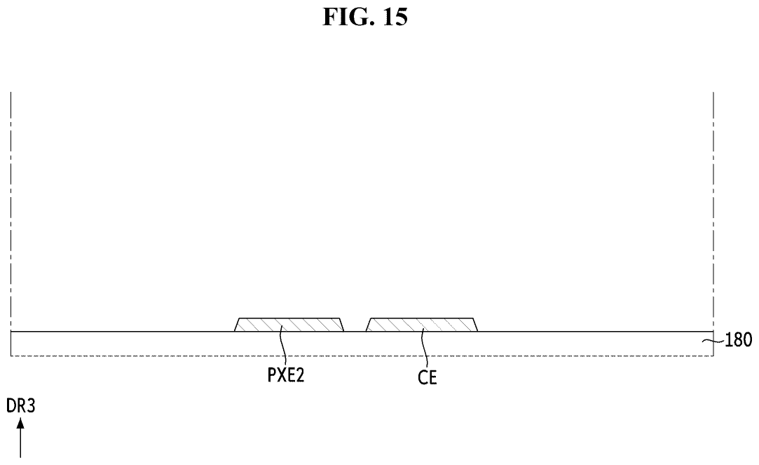

FIG. 15-FIG. 23 are cross-sectional views of manufacturing steps of a display device according to one or more embodiments. Hereinafter, a method for manufacturing a display device will be described with reference to FIGS. 15-23, which are attached to FIG. 14.

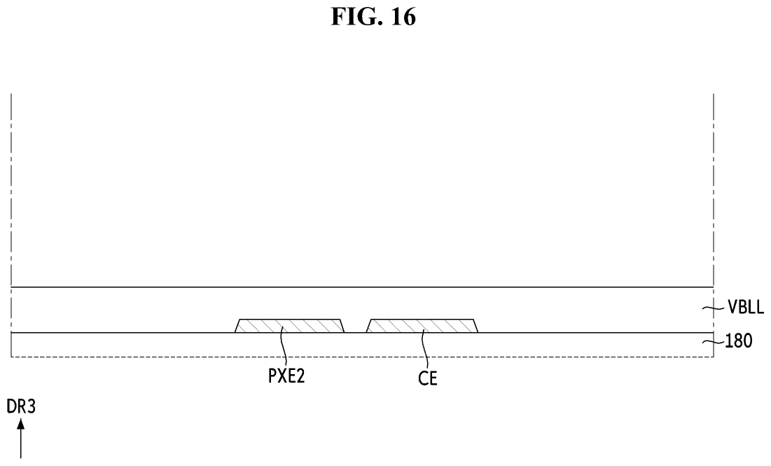

The method for manufacturing a display device described with reference to FIGS. 15-16, which are attached to FIG. 14, may be a display device including a light emitting element and a display panel described with reference to FIGS. 10 and 13.

Referring to FIG. 15, pixel electrodes PXE and a common electrode CE of a backplane substrate are formed. (S110 in FIG. 14)

For example, an electrode material layer may be formed on the entire surface of the backplane substrate and a photolithography process may be performed to form island-shaped pixel electrodes PXE and a common electrode CE. The photolithography process may include a process of applying a photoresist on the electrode material layer and exposing, developing, and etching the photoresist using a mask.

Here, the backplane substrate may include the substrate SUB described in FIG. 10, and the thin-film transistor layer TFTL.

Referring to FIGS. 16-19, a via layer VBL and a reflective partition wall BWL are formed. (S120 in FIG. 14)

For example, referring to FIG. 16, an organic material is applied to a certain thickness on a second planarization organic film 180 to form a via material layer VBLL.

The height of the via material layer VBLL is formed by considering the height of the pixel electrode PXE or the common electrode CE in the third direction and the height of the conductive bonding material layer. The conductive bonding material layer is called a conductive bonding pattern CBP after the bonding process.

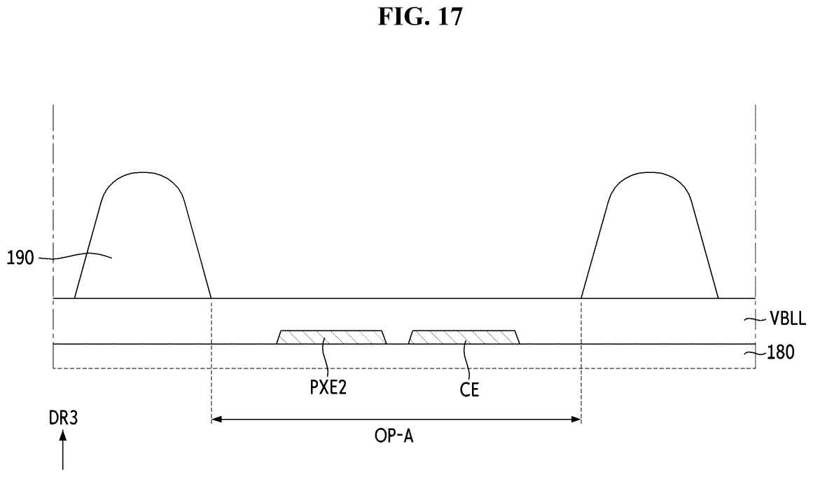

Then referring to FIG. 17, a first organic layer 190 including a first opening area OP-A is formed on the via material layer VBLL. The first organic layer 190 may be formed by patterning an organic material using a photolithography technique but is not limited thereto. The first organic layer 190 may also be formed using an inkjet technique. The height of the first organic layer 190 is formed by considering the height of the light emitting element LE, the depth at which the light emitting element LE is embedded in the conductive bonding pattern CBP, the depth at which the light emitting element LE is embedded in the relay substrate, the thickness of the reflective film RF, and/or the like. For example, referring to FIG. 22, the combined height f-a of the first organic layer 190 and the thickness f-b of the reflective film RF is the height f of the reflective partition wall BWL. The height f of the reflective partition wall BWL should be less than the length h-LE of the light emitting element LE minus the depth e at which the light emitting element LE is embedded in the conductive bonding pattern CBP and the depth a at which the light emitting element LE is embedded in the relay substrate.

On the other hand, when other specifications in the bonding process, such as the size and pressure of the light emitting element LE, are determined, the depth e at which the light emitting element LE is embedded in the conductive bonding pattern CBP and the depth a at which the light emitting element LE is embedded in the relay substrate are fixed. Further, the thickness of the reflective film RF may be adjusted by the process time, etc.

Therefore, in the step of forming reflective partition wall BWL, the depth e at which the light emitting element LE is embedded in the conductive bonding pattern CBP and the depth a at which the light emitting element LE is embedded in the relay substrate may be considered in advance and the height of the reflective partition wall BWL may be set by the mathematical expression 1 described above.

This will be further explained with reference to FIG. 22.

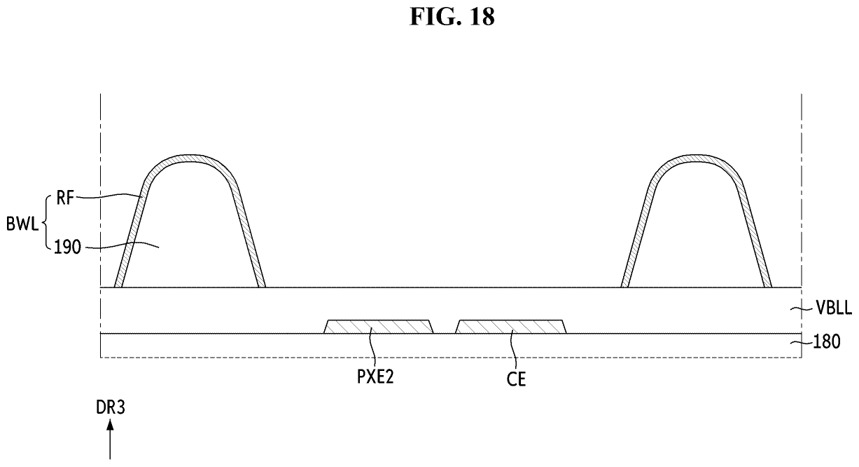

Then, referring to FIG. 18, a reflective film RF is formed on the first organic layer 190.

A reflective material layer is deposited on the first organic layer 190. The deposition may be performed by a conventionally known method such as CVD, PVD, sputter, or ALD.

The reflective material layer that does not overlap with the first organic layer 190 is removed. Accordingly, a reflective film RF is formed.

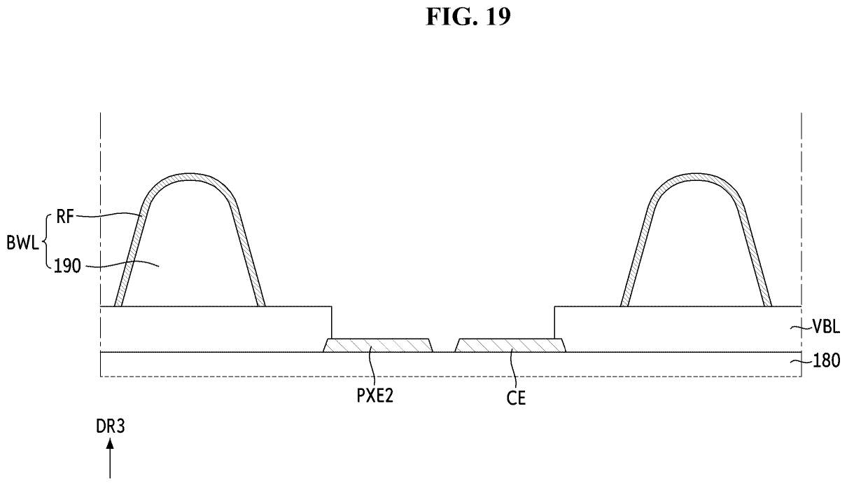

Referring to FIG. 19, the via material layer VBLL on the pixel electrodes PXE1, PXE2, and PXE3 and the common electrode CE is removed so that a portion of the pixel electrodes PXE1, PXE2, and PXE3 and the common electrode CE is exposed, thereby forming a via layer VBL.

Referring to FIG. 20, a conductive bonding pattern CBP is formed (S130 in FIG. 14)

The conductive bonding pattern CBP may be formed by a photolithography process.

For example, for this purpose, a conductive bonding material including a polymer resin and conductive nanoparticles is filled into an opening formed by a via layer VBL. After forming a mask with a photoresist in an area that does not overlap with the pixel electrodes PXE1, PXE2, and PXE3 and the common electrode CE, a first conductive bonding pattern CBP1 is formed on the pixel electrodes PXE1, PXE2, and PXE3 through an exposure and development process, and a second conductive bonding pattern CBP2 is formed on the common electrode CE. The top surface of the via layer VBL and the top surface of the conductive bonding pattern CBP1 and CBP2 may be formed flat on the same layer.

Referring to FIGS. 21 and 22, heat and pressure are applied to the conductive bonding pattern CBP to transfer and bond the light emitting element LE. (S140 in FIG. 14)

In one or more embodiments, the light emitting element LE is placed so that the first conductive bonding pattern CBP1 and the second conductive bonding pattern CBP2 face each other.

The light emitting element LE may be arranged on the second substrate SSB. The second substrate SSB may be, for example, a relay substrate. The relay substrate may be composed of a support layer and an adhesive layer PDMS arranged on the support layer. The support layer may be made of a material that is transparent and mechanically stable so that light may pass through. For example, the support layer may include a transparent polymer such as polyester, polyacrylic, polyepoxy, polyethylene, polystyrene, polyethylene terephthalate, and/or the like. The adhesive layer may include a bonding material for bonding the light emitting element LE. The bonding material may be an organic silicon chemical such as polydimethylsiloxane (PDMS). PDMS may have adhesiveness. The adhesiveness may allow the light emitting element LE to be adhered to the second substrate SSB.

The light emitting element LE may be transferred while being partially embedded in the adhesive layer. The depth a of the light emitting element LE embedded in the adhesive layer PDMS may be about 0.8 μm but is not limited thereto. For example, the depth a of the light emitting element LE embedded in the adhesive layer PDMS may be equal to or deeper than the depth of the unevenness of the light extraction pattern LEP of the light emitting element LE. Thus, the adhesive layer may be arranged on one side of the light emitting element LE.

Then, a pressure member PM is arranged on the second substrate SSB, and a laser irradiator LS is arranged on top of the pressure member PM to provide heat and pressure to the first conductive bonding pattern CBP1 and the second conductive bonding pattern CBP2.

The pressure member PM may be formed of a material that transmits light. For example, the pressure member PM may be implemented with one of quartz, sapphire, fused silica glass, or diamond. However, in the case of quartz, a laser transmittance of 85% to 99% may be preferred.

The laser irradiator LS is arranged on top of the pressure member PM, and a laser beam LB is irradiated to the first conductive bonding pattern CBP1 and the second conductive bonding pattern CBP2. A laser beam LB emitted from a laser irradiator LS passes through a pressure member PM and is irradiated to the first conductive bonding pattern CBP1 and the second conductive bonding pattern CBP2.

While the laser is irradiated to the first conductive bonding pattern CBP1 and the second conductive bonding pattern CBP2 by the laser irradiator LS, the pressure member PM presses the light emitting element LE toward the first conductive bonding pattern CBP1 and the second conductive bonding pattern CBP2. The pressure member PM may pressurize at a pressure of about 5 MPa but is not limited thereto.

The light emitting element LE is pressed and fixed to be partially embedded in the first conductive bonding pattern CBP1 and the second conductive bonding pattern CBP2. At this time, because the second substrate SSB overlaps the reflective partition wall BWL in the third direction DR3, if the height of the reflective partition wall BWL is high, the reflective partition wall BWL and the second substrate SSB come into contact, and the pressure applied by the pressure member PM may not be transmitted to the light emitting element LE due to the resistance of the reflective partition wall BWL. In other words, the pressure transmitted by the pressure member PM may be transmitted to the reflective partition wall BWL. As a result, the light emitting element LE may not receive sufficient pressure to be embedded in the conductive bonding pattern CBP. Also, if the height of the reflective partition wall BWL is high, it may be difficult for the heat source output from the laser irradiator LS to be easily transmitted to the conductive bonding pattern CBP. In this case, it may take a long time to reach the bonding temperature (approximately 140° C.). Furthermore, if the top surface of the reflective partition wall BWL surrounding the light emitting element LE is not flat (e.g., if the heights of the reflective partition walls BWL on the left and right sides of the light emitting element LE are different in the cross-section), the second substrate SSB will not be level, which will make it difficult to apply even pressure to the entire display area. Therefore, the possibility of a bonding failure in each area may increase.

Thus, a bonding defect may occur between the light emitting element LE and the conductive bonding pattern CBP, and further, a lighting failure of the light emitting element LE may occur.

Therefore, the height f of the reflective partition wall BWL may be equal to or smaller than the length of the light emitting element LE minus the depth e at which the light emitting element LE is embedded in the conductive bonding pattern CBP and the depth a at which the light emitting element LE is embedded in the relay substrate. Here, the height f-a of the first organic layer 190 and the thickness f-b of the reflective film RF are combined to form the height f of the reflective partition wall BWL.

In one or more embodiments, a laser beam may be irradiated on the conductive nanoparticles to perform bonding and post-curing. To concurrently (e.g., simultaneously) perform bonding and post-curing by irradiating the laser beam, the process temperature is heated to 140° C. by irradiating the laser beam with the first power for a first time, and the process temperature is heated to 260° C. by irradiating the laser beam with the second power for a second time. The second power may be a higher power than the first power. The first time may be about 3 seconds, and the second time may be about 2 seconds.

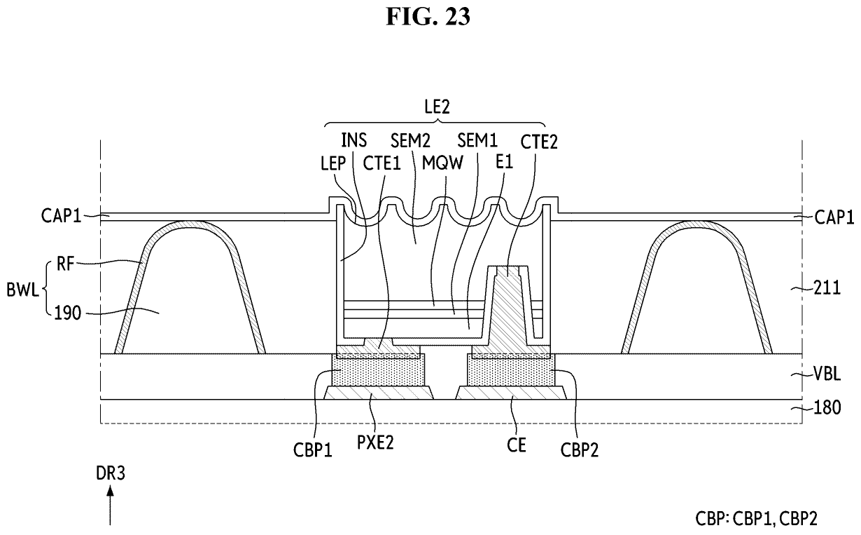

Then, when the irradiation is completed, the pressure member PM is raised, and the second substrate SSB is separated and removed from the light emitting element LE, as shown in FIG. 23.

Because the adhesive strength between the second substrate SSB and the light emitting element LE is weaker than the adhesive strength between the light emitting element LE and the conductive bonding pattern CBP, the second substrate SSB and the light emitting element LE may be easily physically separated.

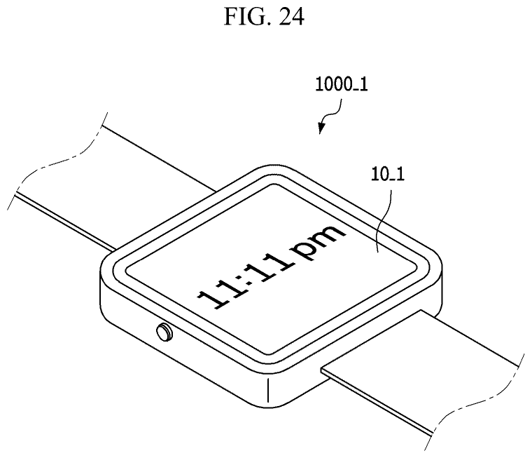

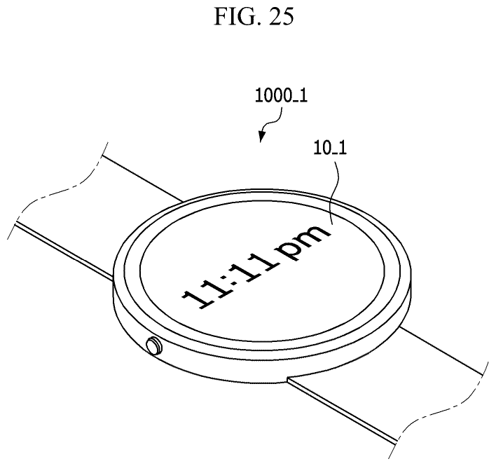

FIGS. 24 and 25 are example drawings illustrating a smart watch including a display device according to one or more embodiments.

Referring to FIGS. 24 and 25, a display device 10_1 according to one or more embodiments may be applied to a smart watch 1000_1, which is one of smart devices.

The flat shape of the display device 10_1 may be a square or a circle but is not limited thereto and may be modified in various ways, such as an oval.

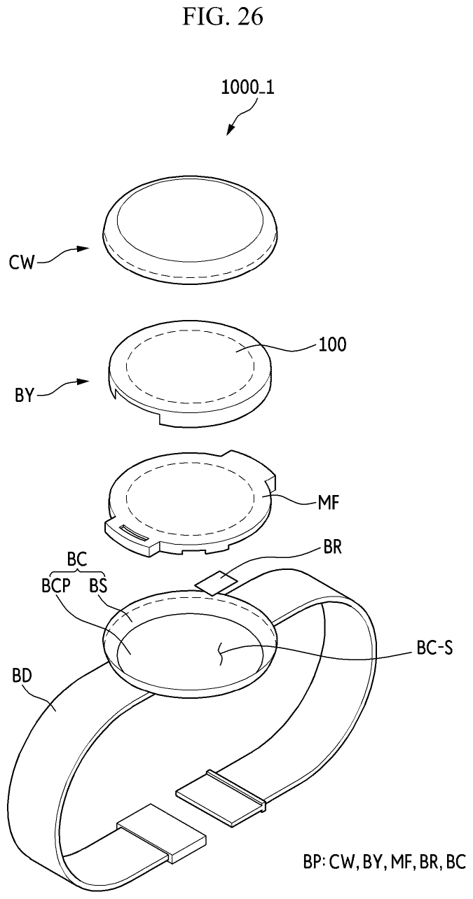

FIG. 26 is an exploded perspective view of a smart watch including a display device according to one or more embodiments.

Referring to FIG. 26, the smart watch 1000_1 may include a main body unit BP and a wearable portion BD.

The main body unit BP may include a display panel 100 on which an image is displayed, a cover window CW disposed on the display panel 100, a bottom cover BC disposed under the display panel 100, a middle frame MF disposed between the cover window CW and the bottom cover BC, and a battery BR disposed between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 100 to protect the display panel 100 and to transmit light emitted from the display panel 100. As described above, the cover window CW may include a light-blocking portion to block a portion of the light emitted from the display panel 100. The cover window CW may be made of a transparent plastic material, a glass material, or a reinforced glass material.

The cover window CW may be arranged to overlap the display panel 10 and cover the front of the display panel 100. The cover window CW generally has a shape similar to that of the display panel 100 in terms of a plane, but its size may be larger than that of the display panel 100. For example, the cover window CW may protrude outward from the display panel 100. The plane shape of the cover window CW may be the same as that of the main body unit BP. For example, the planar shape of the cover window CW may be generally circular but is not limited thereto and may have various shapes, for example, a polygon such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 10.

The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to be around (e.g., to surround) the central cover portion BCP. The peripheral portion BS may be a portion that is bent and curved from the central cover portion BCP. The peripheral portion BS may be bent from the edge of the central cover portion BCP. In some embodiments, the peripheral portion BS may include a curved surface having a suitable curvature (e.g., a predetermined curvature), and the other portion may be flat. The degree (or angle) at which the peripheral portion BS is bent from the central cover portion BCP may be an obtuse angle, but is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and/or the like.

The bottom cover BC is placed on the outermost rear surface of the electronic device and may include at least one of a plastic material, a metal material, and a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body unit BP to the user's wrist, for example, and may be one of a strap, a chain, and a bracelet.

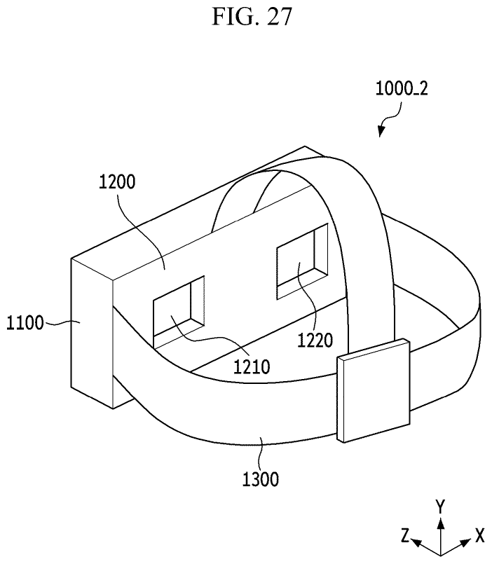

FIG. 27 is example views of a virtual reality (VR) device including a display device according to one or more embodiments.

Referring to FIG. 27, a head mounted display device 1000_2 according to one or more embodiments includes a display device housing 1100, a housing cover 1200, a first eyepiece 1210, a second eyepiece 1220, and head mounted band 1300.

The display device housing 1100 houses a display device. A head mounted display device 1000_2 according to one or more embodiments further include a first optical member disposed between the first display device and the first eyepiece 1210.

The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 31, the present disclosure is not limited thereto. The first eyepiece 1210 and the second eyepiece 1220 may also be combined into one.

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 27 instead of the head mounted band 1300.

The display device housing 1100 houses display device. In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

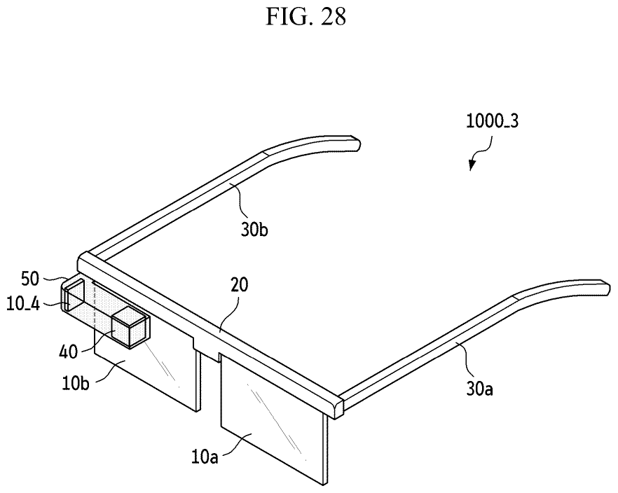

FIG. 28 is an example view of a VR device including a display device according to one or more embodiments. FIG. 28 illustrates a VR device 1000_3 to which a display device 10_4 according to one or more embodiments has been applied.

Referring to FIG. 28, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 28, a case where the VR device 1000_3 is a glasses-type display device including the eyeglass frame legs 30a and 30b is illustrated as an example. That is, the VR device 1000_3 according to the embodiment is not limited to the one illustrated in FIG. 28 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 28, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

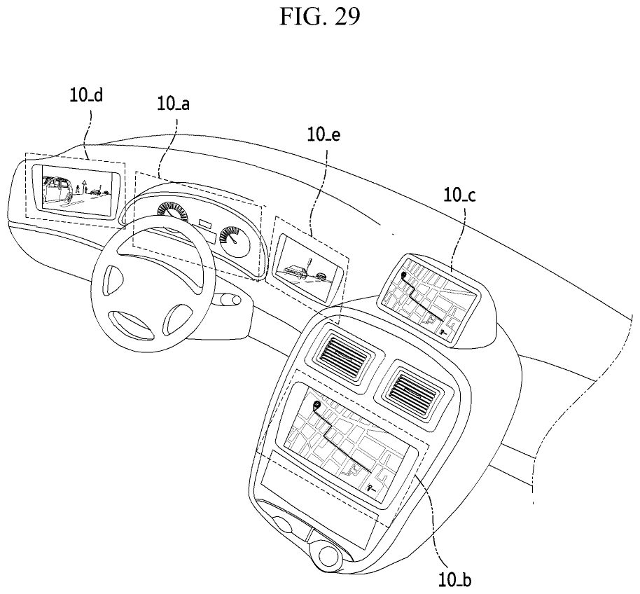

FIG. 29 is an example view illustrating a vehicle instrument cluster and center fascia including display devices according to one or more embodiments. FIG. 29 illustrates a vehicle to which display devices 10_a through 10_e according to one or more embodiments have been applied.

Referring to FIG. 29, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

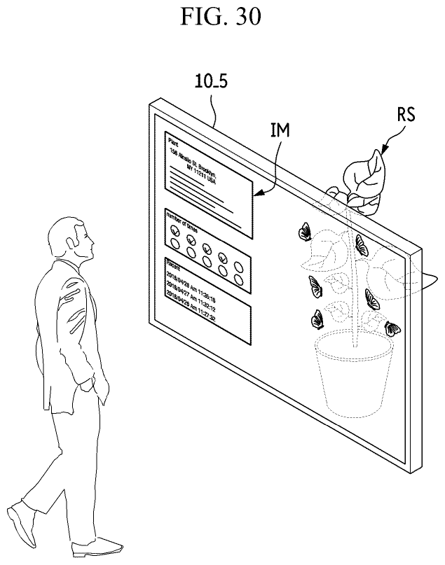

FIG. 30 is an example view of a transparent display device including a display device according to one or more embodiments.

Referring to FIG. 30, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A method for manufacturing a display device comprising:
forming a first electrode on a first substrate;
forming a via layer on the first substrate, and forming a reflective partition wall on the via layer;
forming a conductive bonding pattern on the first electrode;
arranging a second substrate, on which a light emitting element is arranged, on the conductive bonding pattern, wherein the light emitting element comprises a contact electrode arranged on one surface, and wherein an adhesive layer is on one surface of the second substrate; and
bonding the light emitting element using the conductive bonding pattern by irradiating the adhesive layer with a laser beam by a laser irradiator and pressing the light emitting element with the conductive bonding pattern by pressing a pressing member in a direction in which the conductive bonding pattern is arranged on the second substrate,
wherein a height of the reflective partition wall is based on a height of the light emitting element, a depth at which the light emitting element is embedded in the conductive bonding pattern, and a depth at which the light emitting element is embedded in the adhesive layer of the second substrate.

2. The method of claim 1, wherein the height of the reflective partition wall is a length of the height of the light emitting element excluding a depth at which the light emitting element is embedded in the adhesive layer of the second substrate and a depth at which the light emitting element is embedded in the conductive bonding pattern.

3. The method of claim 1, wherein the height of the light emitting element is a body length of the light emitting element and a thickness of the contact electrode,
wherein the body length of the light emitting element is a distance from a top surface of the light emitting element to an interface between the light emitting element and the contact electrode.

4. The method of claim 1, in the forming the conductive bonding pattern,
wherein a top surface of the conductive bonding pattern is flat on the same layer as a top surface of the via layer.

5. The method of claim 1, the forming the via layer on the first substrate, and the forming the reflective partition wall on the via layer comprising:
forming a via material layer on an entire surface of the first substrate to cover the first electrode;
forming an organic layer including a first opening area on the via material layer;
forming a reflective film on the organic layer to form the reflective partition wall; and
etching a portion of the via material layer to form the via layer so that at least a portion of the first electrode is exposed.

6. The method of claim 5, before the forming the reflective partition wall by forming the reflective film on the organic layer,
wherein a first protective layer is formed on the organic layer,
wherein a second protective layer is formed on the reflective film after the forming the reflective film on the organic layer.

7. The method of claim 1, wherein the conductive bonding pattern comprises a polymer resin and conductive nanoparticles dispersed in the polymer resin.

8. The method of claim 7, wherein the conductive nanoparticles are conductive carbon black.

9. The method of claim 1, wherein the light emitting element comprises:
a first semiconductor layer doped with a first conductive dopant;
a second semiconductor layer doped with a second conductive dopant;
an active layer arranged between the first semiconductor layer and the second semiconductor layer;
a protective film arranged on side surfaces of the first semiconductor layer, the active layer, and the second semiconductor layer; and
the contact electrode arranged on a bottom surface of the first semiconductor layer.

10. The method of claim 9, wherein the contact electrode comprises a first contact electrode and a second contact electrode.

11. The method of claim 10, in forming the first electrode on the first substrate,
wherein a second electrode is formed spaced from the first electrode when the first electrode is formed on the first substrate.

12. The method of claim 9, wherein a top surface of the light emitting elements has a concave-convex structure having a cross-sectional shape of a semicircle or a semi-ellipse.

13. The method of claim 12, wherein the concave-convex structure is embedded in the adhesive layer of the second substrate.

14. The method of claim 1, further comprising separating the second substrate from the light emitting element.

15. A method for manufacturing an electronic device comprising a display device, the method comprising:
forming a first electrode on a first substrate;
forming a reflective partition wall on the first substrate;
forming a conductive bonding pattern on the first electrode;
arranging a second substrate, on which a light emitting element is arranged, on the conductive bonding pattern, wherein the light emitting element comprises a contact electrode arranged on one surface, and wherein an adhesive layer is on one surface of the second substrate; and
bonding the light emitting element using the conductive bonding pattern by irradiating the adhesive layer with a laser beam by a laser irradiator and pressing the light emitting element with the conductive bonding pattern by pressing a pressing member in a direction in which the conductive bonding pattern is arranged on the second substrate,
wherein a height of the reflective partition wall is based on a height of the light emitting element, a depth at which the light emitting element is embedded in the conductive bonding pattern, a depth at which the light emitting element is embedded in the adhesive layer of the second substrate, a height of the first electrode, and a height of the conductive bonding pattern.

16. The method of claim 15, wherein a height of the reflective partition wall is a length excluding a depth at which the light emitting element is embedded in the adhesive layer of the second substrate and a depth at which the light emitting element is embedded in the conductive bonding pattern from a height of the light emitting element, a height of the first electrode, and a height of the conductive bonding pattern.

17. The method of claim 15, wherein the conductive bonding pattern comprises a polymer resin and conductive nanoparticles dispersed in the polymer resin.

18. The method of claim 17, wherein the conductive nanoparticles are conductive carbon black.

19. The method of claim 15, wherein a top surface of the light emitting elements has a concave-convex structure having a cross-sectional shape of a semicircle or a semi-ellipse,
wherein the concave-convex structure is embedded in the adhesive layer of the second substrate.

20. The method of claim 15, further comprising separating the second substrate from the light emitting elements.
